(19) United States
(12) Patent Application Publication
(10) Pub. No.: US 2024/0172373 A1
(43) Pub. Date: May 23, 2024

(54) PRINTED CIRCUIT BOARD AND MANUFACTURING METHOD FOR THE SAME

(71) Applicant: SAMSUNG ELECTRO-MECHANICS CO., LTD., Suwon-si (KR)

(72) Inventors: Byung Woo Kim, Suwon-si (KR); Choon Keun Lee, Suwon-si (KR)

(73) Assignee: SAMSUNG ELECTRO-MECHANICS CO., LTD., Suwon-si (KR)

(21) Appl. No.: 18/232,119

(22) Filed: Aug. 9, 2023

(30) Foreign Application Priority Data
Nov. 17, 2022 (KR) 10-2022-0154745
Apr. 4, 2023 (KR) 10-2023-0044272

(51) Int. Cl. H05K 3/46; H05K 1/11; H05K 3/00

(52) U.S. Cl. CPC H05K 3/4661; H05K 1/115; H05K 3/0017; H05K 2203/0228

(57) ABSTRACT

A manufacturing method for a printed circuit board includes: forming a first substrate portion; forming an intermediate insulating layer on the first substrate portion; forming a temporary layer on a surface opposite to a surface on which the intermediate insulating layer of the first substrate portion is formed; flattening the temporary layer; forming a second substrate portion on the intermediate insulating layer; and removing the temporary layer.

### CROSS-REFERENCE TO RELATED APPLICATION(S)

This application claims benefit of priority to Korean Patent Application No. 10-2022-0154745 and 10-2023-0044272 filed on Nov. 17, 2022, and Apr. 4, 2023, in the Korean Intellectual Property Office, the disclosures of which are incorporated herein by reference in its entirety.

### TECHNICAL FIELD

The present disclosure relates to a printed circuit board and a manufacturing method for the same.

In order to cope with a recent trend of light weight and miniaturization of mobile devices, there is an increasing need to miniaturize and thin printed circuit boards mounted thereon. Furthermore, with an increase in the demand for high-performance server-oriented printed circuit boards, demand for a logic semiconductor and a memory semiconductor, or a high-density circuit for connecting the logic semiconductor and the logic semiconductor, is also rapidly increasing. In this case, if a bottom surface of an insulating layer is not flattened in the process of implementing a high-density circuit, defects in the high-density circuit may occur. In response to a technical demand therefor, a research continues to improve reliability while implementing high-density microcircuits.

### SUMMARY

An aspect of the present disclosure is to provide a printed circuit board to implement a region including a fine circuit, and a manufacturing method for the printed circuit board.

Another aspect of the present disclosure is to provide a printed circuit board for flattening a substrate before forming a region including a fine circuit, and a manufacturing method for the printed circuit board.

Another aspect of the present disclosure is to provide a printed circuit board to improve reliability, and a manufacturing method for the printed circuit board.

According to an aspect of the present disclosure, a manufacturing method for a printed circuit board includes: forming a first substrate portion; forming an intermediate insulating layer on the first substrate portion; forming a temporary layer on a surface opposite to a surface on which the intermediate insulating layer of the first substrate portion is formed; flattening the temporary layer; forming a second substrate portion on the intermediate insulating layer; and removing the temporary layer.

According to another aspect of the present disclosure, a printed circuit board includes: a first substrate portion including a plurality of first insulating layers, a plurality of first wiring layers respectively disposed on or in the plurality of first insulating layers, and a plurality of first via layers penetrating through at least a portion of one or more of the plurality of first insulating layers; a second substrate portion disposed on the first substrate portion; and an intermediate insulating layer disposed between the first and second substrate portions. At least one first wiring of a first wiring layer disposed lowermost, among the plurality of first wiring layers, is disposed on the first via, and the first substrate portion includes a gap region for separating at least a portion of at least one first via of a first via layer disposed lowermost, among the plurality of first via layers, from a first insulating layer disposed lowermost, among the plurality of first insulating layers.

According to an aspect of the present disclosure, a manufacturing method for a printed circuit board includes: forming a first substrate portion; forming an intermediate insulating layer on the first substrate portion; forming a temporary layer on a surface opposite to a surface on which the intermediate insulating layer of the first substrate portion is formed; leveling an exterior surface of the temporary layer by thinning the temporary layer, such that the exterior surface of the temporary layer after leveling is substantially parallel to a surface of the intermediate insulating layer opposite to the first substrate portion; forming a second substrate portion on the intermediate insulating layer; and removing the temporary layer.

According to another aspect of the present disclosure, a printed circuit board includes: a first substrate portion including a plurality of first insulating layers, a plurality of first wiring layers respectively disposed on or in the plurality of first insulating layers, and a plurality of first via layers penetrating through at least a portion of one or more of the plurality of first insulating layers; a second substrate portion disposed on the first substrate portion, and including a plurality of second insulating layers, a plurality of second wiring layers respectively disposed on or in the plurality of second insulating layers, and a plurality of second via layers penetrating through at least a portion of one or more of the plurality of second insulating layers; and an intermediate insulating layer disposed between the first and second substrate portions. A thickness, along a first side surface of the second substrate portion, of the second substrate portion is substantially identical to a thickness, along a second side surface facing the first side surface of the second substrate portion, of the second substrate portion. A thickness, along a first side surface of the first substrate portion, of the first substrate portion is thicker than a thickness, along a second side surface facing the first side surface of the first substrate portion, of the first substrate portion.

As one of various effects of the present disclosure is to provide a printed circuit board to implement a region including a fine circuit, and a manufacturing method for the printed circuit board.

As another effect of various effects of the present disclosure is to provide a printed circuit board for flattening a substrate before forming a region including a fine circuit, and a manufacturing method for the printed circuit board.

As another effect of various effects of the present disclosure is to provide a printed circuit board to improve reliability, and a manufacturing method for the printed circuit board.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example embodiment of an electronic device system;

FIG. 2 is a perspective view schematically illustrating an example embodiment of an electronic device;

FIG. 3 is a flowchart illustrating a manufacturing method for a printed circuit board according to an example embodiment;

FIGS. 4 to 13 are cross-sectional views schematically illustrating a manufacturing method for a printed circuit board according to an example embodiment;

FIG. 14 is a cross-sectional view schematically illustrating a portion of a manufacturing method for a printed circuit board according to another example embodiment;

FIG. 15 is a cross-sectional view schematically illustrating a portion of a manufacturing method for a printed circuit board according to another example embodiment;

FIGS. 16 to 18 are cross-sectional views schematically illustrating a portion of a manufacturing method for a printed circuit board according to another example embodiment;

FIG. 19 is a cross-sectional view schematically illustrating a printed circuit board according to another example embodiment;

FIG. 20 is a cross-sectional view schematically illustrating a printed circuit board according to another example embodiment;

FIG. 21 is a cross-sectional view schematically illustrating a printed circuit board according to another example embodiment;

FIG. 22 is a cross-sectional view schematically illustrating a printed circuit board according to another example embodiment;

FIG. 23 is a flowchart illustrating a manufacturing method for a printed circuit board according to another example embodiment;

FIGS. 24 to 32 are cross-sectional views schematically illustrating a manufacturing method for a printed circuit board according to another example embodiment;

FIGS. 33 to 36 are cross-sectional views schematically illustrating a portion of a manufacturing method for a printed circuit board according to another example embodiment;

FIG. 37 is a cross-sectional view schematically illustrating a portion of a manufacturing method for a printed circuit board according to another example embodiment;

FIG. 38 is a cross-sectional view schematically illustrating a printed circuit board according to another example embodiment; and

FIG. 39 is a cross-sectional view schematically illustrating a printed circuit board according to another example embodiment.

### DETAILED DESCRIPTION

Hereinafter, example embodiments of the present disclosure will be described with reference to the attached drawings. The shape and size of the components in the drawings may be exaggerated or reduced for clearer description.

### Electronic Device

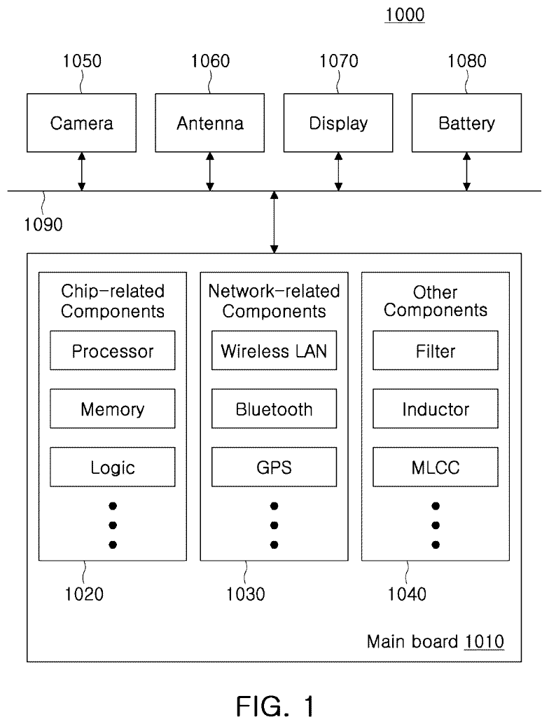

FIG. 1 is a block diagram schematically illustrating an example embodiment of an electronic device system.

Referring to FIG. 1, an electronic device 1000 accommodates a main board 1010. Chip-related components 1020, network-related components 1030, and other components 1040 are physically and/or electrically connected to the main board 1010. They are combined with other electronic components described below to form various signal lines 1090.

The chip-related components 1020 may include memory chips such as a volatile memory (e.g., a DRAM), a non-volatile memory (e.g., a ROM), and a flash memory; application processor chips such as a central processor (e.g., a CPU), a graphics processor (e.g., a GPU), a digital signal processor, an encryption processor, a microprocessor, and a microcontroller; and logic chips such as an analog-to-digital converter and an application-specific IC (ASIC), but the present disclosure is not limited thereto, and the chip-related components 1020 may include other types of chip-related electronic components. Furthermore, the chip-related components 1020 may be combined with each other. The chip-related component 1020 may be in the form of a package including the aforementioned chips or electronic components.

The network-related components 1030 may include Wi-Fi (such as the IEEE 802.11 family), WiMAX (such as the IEEE 802.16), IEEE 802.20, long term evolution (LTE), Ev-DO, HSPA+, HSDPA+, HSUPA+, EDGE, GSM, GPS, GPRS, CDMA, TDMA, DECT, Bluetooth, 3G, 4G and 5G, and any other wireless and wired protocols designated as thereafter, but the present disclosure is not limited thereto, and the network-related components 1030 may include any of a number of other wireless or wired standards or protocols. Furthermore, the network-related components 1030 may be combined with the chip-related components 1020.

Other components 1040 include a high-frequency inductor, a ferrite inductor, a power inductor, a ferrite bead, low Temperature Co-Firing Ceramics (LTCC), an Electro Magnetic Interference (EMI) filter, a Multi-Layer Ceramic Condenser (MLCC). However, the present disclosure is not limited thereto, and other components 1040 may include manual elements in the form of chip components used for various other purposes. Furthermore, other components 1040 may be combined with the chip-related components 1020 and/or the network-related components 1030.

Depending on the type of electronic device 1000, the electronic device 1000 may include other electronic components that may or may not be physically and/or electrically connected to the main board 1010. Examples of other electronic components include a camera module 1050, an antenna module 1060, a display 1070 and a battery 1080. However, the present disclosure is not limited thereto, and other electronic components may be an audio codec, a video codec, a power amplifier, a compass, an accelerometer, a gyroscope, a speaker, a mass storage device (e.g., a hard disk drive), a compact disk (CD), and a digital versatile disk (DVD). Furthermore, other electronic components used for various purposes may be included depending on the type of the electronic device 1000.

The electronic device 1000 includes a smartphone, a personal digital assistant, a digital video camera, a digital still camera, a network system, a computer, a monitor, a tablet, a laptop, a netbook, a television, a video game, a smartwatch, and an automotive component. However, the present invention is not limited thereto, and the electronic device 1000 may be any other electronic device for processing data in addition to the aforementioned devices.

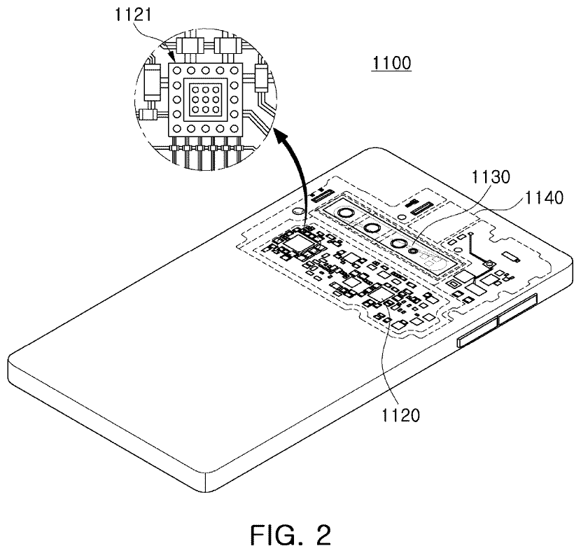

FIG. 2 is a perspective view schematically illustrating an example embodiment of an electronic device.

Referring to FIG. 2, the electronic device may be, for example, a smartphone 1100. A motherboard 1110 is accommodated in the smartphone 1100, and various components 1120 are physically and/or electrically connected to the motherboard 1110. Furthermore, other components that may or may not be physically and/or electrically connected to the motherboard 1110 such as a camera module 1130 and/or a speaker 1140 are accommodated inside. Some of the components 1120 may be chip-related components described above, for example, a component package 1121, but the present disclosure is not limited thereto. The component package 1121 may be in the form of a printed circuit board in which an electronic component including an active component and/or a manual component is surface-mounted. Alternatively, the component package 1121 may be in the form of a printed circuit board in which an active component and/or a manual component is embedded. Meanwhile, the electronic device is not necessarily limited to the smartphone 1100, and may be other electronic devices as described above.

### Manufacturing Method for Printed Circuit Board

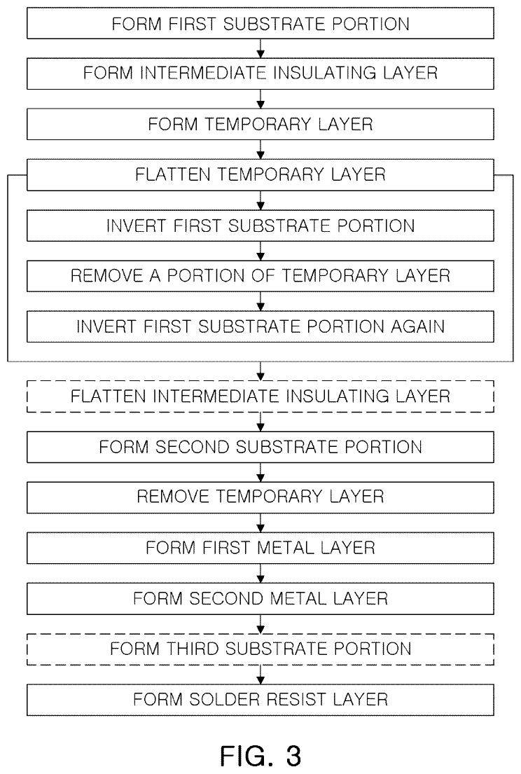

FIG. 3 is a flowchart illustrating a manufacturing method for a printed circuit board according to an example embodiment.

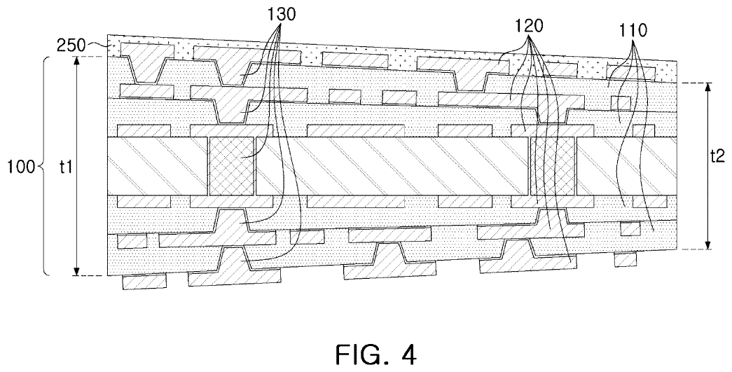

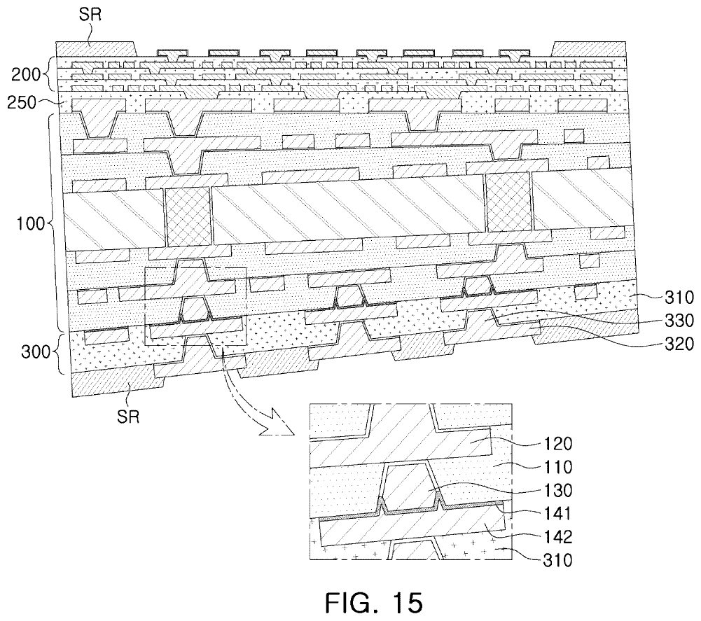

FIGS. 4 to 14 are cross-sectional views schematically illustrating a manufacturing method for a printed circuit board according to an example embodiment. FIG. 15 is a cross-sectional view schematically illustrating a portion of a manufacturing method for a printed circuit board according to another example embodiment.

According to the drawings, a manufacturing method for a printed circuit board according to an example embodiment may include an operation of forming a first substrate portion 100, an operation of forming an intermediate insulating layer 250, an operation of forming a temporary layer 400, an operation of flattening the temporary layer 400, flattening the intermediate insulating layer 250, an operation of forming a second substrate portion 200, an operation of removing the temporary layer 400, an operation of forming a first metal layer 141, an operation of forming a second metal layer 142, an operation of forming a third substrate portion 300, and an operation of forming a solder resist layer SR.

The operation of flattening the temporary layer 400 may include an operation of inverting the first substrate portion 100, an operation of removing a portion of the temporary layer 400, and an operation of inverting the first substrate portion 100 again.

Referring to FIG. 4, a manufacturing method for a printed circuit board according to an example embodiment may include the operation of forming the first substrate portion 100 and the operation of forming the intermediate insulating layer 250.

The operation of forming the first substrate portion 100 may include an operation of forming a plurality first wiring layers 120, a plurality of first insulating layers 110 burying the plurality of first wiring layers 120, and a first via layer 130 penetrating through at least a portion of each of the plurality of first insulating layers 110.

The first substrate portion 100 may be a core type multilayer substrate. That is, the plurality of first insulating layers 110 may include a core insulating layer and a plurality of build-up insulating layers, and the plurality of build-up insulating layers may be formed above and below the core insulating layer to form the plurality of first insulating layers 110. The plurality of first wiring layers 120 may include a core wiring layer and a plurality of build-up wiring layers disposed on an upper surface and a lower surface of the core insulating layer, respectively. Furthermore, the plurality of first via layers 130 may include a through-via layer penetrating through the core insulating layer to connect the core wiring layers to each other and a connection via layer penetrating through the plurality of build-up insulating layers to connect the plurality of build-up wiring layers to each other.

The core insulating layer of the first insulating layer 110 may include an insulating material. The insulating materials may include a thermosetting resin such as an epoxy resin, a thermoplastic resin such as polyimide, a material in which these insulating resins are mixed with an inorganic filler such as silica, or a resin impregnated with core materials such as glass fibers (e.g., glass fiber, glass cloth, and glass fabric) along with the inorganic filler, for example, an insulating material of a copper clad laminate (CCL) may be used, but the present disclosure is not limited thereto. The core insulating layer may be thicker than each of the plurality of build-up insulating layers, but the present disclosure is not limited thereto.

Each of the build-up insulating layers of the first insulating layer 110 may include an insulating material. The insulating material may include a thermosetting resin such as an epoxy resin, a thermoplastic resin such as polyimide, or a material including an inorganic filler, an organic filler, and/or glass fibers (e.g., glass fiber, glass cloth, and/or glass fabric) along with these resins. The insulating material may be a photosensitive material and/or a non-photosensitive material. For example, the insulating material of the plurality of build-up insulating layers may be an insulating material of Prepreg (PPG) or resin coated copper (RCC), but the present disclosure is not limited thereto, and the insulating material may be an Ajinomoto build-up film (ABF), a photo imagable dielectric, FR-4, Bismaleimide Triazine (BT). However, the present disclosure is not limited thereto, and if necessary, other polymer materials having excellent rigidity may be used.

Each of the first wiring layers 120 may include a metal material. As the metal material, copper (Cu), aluminum (Al), silver (Ag), tin (Sn), gold (Au), nickel (Ni), lead (Pb), titanium (Ti), or alloys thereof may be used. The first wiring layers 120 may include an electroless plating layer (or chemical copper) as a seed layer and an electroplating layer (or electric copper) as a plating layer, respectively, but the present disclosure is not limited thereto. A sputtering layer may be formed instead of chemical copper as the electroless plating layer. If necessary, copper foil may be further included therein. Each of the first wiring layer 120 may perform various functions according to a design of a corresponding layer. For example, the first wiring layer 120 may include a ground pattern, a power pattern, or a signal pattern. Here, the signal pattern may include various signals such as a data signal, except for the ground pattern and the power pattern. Each of these patterns may include a line pattern, a plane pattern, and/or a pad pattern.

The through-via layer of the first via layer 130 may include a metal layer formed on a wall surface of a through-hole and a plug filling the metal layer. The metal layer may include a metal material such as copper (Cu), aluminum (Al), silver (Ag), tin (Sn), gold (Au), nickel (Ni), lead (Pb), titanium (Ti), or alloys thereof. The plug may include ink having an insulating material. The metal layer may include an electroless plating layer (or chemical copper) and an electroplating layer (or electric copper), but the present disclosure is not limited thereto. A sputtering layer may be formed instead of chemical copper as the electroless plating layer. The through-via may perform various functions according to a design. For example, the through-via may include a ground via, a power via, and a signal via. Here, the signal via may include a via for transmitting various signals such as a data signal, except for the ground via and the power via.

The connection via layer of the first via layer 130 may include a micro-via. The micro-via may be a filled via filling a via hole or a conformal via disposed along a wall surface of the via hole. The micro-via may be arranged in a stacked type and/or a staggered type. Each of the first via layers 130 may include a metal material, and the metal material may include copper (Cu), aluminum (Al), silver (Ag), tin (Sn), gold (Au), nickel (Ni), lead (Pb), titanium (Ti), or alloys thereof. The connection via layer may include an electroless plating layer (or chemical copper) as a seed layer and an electrolytic plating layer (or electrolytic copper) as a plating layer, respectively, but the present disclosure is not limited thereto. A sputtering layer may be formed instead of chemical copper as the electroless plating layer. The connection via layer may perform various functions according to a design of a corresponding layer. For example, the connection via layer may include a ground via, a power via, and a signal via. Here, the signal via may include a via for transmitting various signals such as a data signal, except for the ground via and the power via.

Each of the first wiring layers 120 and each of the first via layers 130 may be integrally formed with each other, but the present disclosure is not limited thereto. The first wiring layer 120 and the first via layer 130 may be formed by any one of a semi additive process (SAP) method, a modified semi additive process (MSAP) method, a Tenting (TT) method, or a subtractive method, but the present disclosure is not limited thereto, and any method capable of constructing a circuit on a printed circuit board may be used without limitation.

On the other hand, the first substrate portion 100 is described as having a core insulating layer and a build-up insulating layer comprised of four layers, and the first wiring layer 120 and the first via layer 130 are also described in corresponding numbers, but the present disclosure is not limited thereto, and the number of layers of the first substrate portion 100 may be changed according to the design of the printed circuit board.

Furthermore, although not described in FIG. 4, electronic components comprised of passive elements and/or active elements may be embedded inside the first substrate portion 100, and the first substrate portion 100 may be formed to further include a general configuration of the printed circuit board. That is, the first substrate portion 100 may be formed to further include a manufacturing method that may be used by those skilled in the relevant technology field.

A total thickness variation (TTV) of the first substrate portion 100 may occur in the operation of forming the first insulating layer 110, the first wiring layer 120, and the first via layer 130 of the manufacturing method for a printed circuit board according to an example embodiment. This is because the thickness variation of the first insulating layer 110 formed to bury the first wiring layer 120 may occur by the design of the first wiring layer 120. In other words, a thickness of the first insulating layer 110 may be thick in a region in which a density of the first wiring layer 120 is high, while the thickness of the first insulating layer 110 may be thin in a region in which the density of the first wiring layer 120 is low, and accordingly, a thickness variation may occur in the first insulating layer 110 having one layer. The total thickness variation may be generated by accumulating thickness variation generated in each of the first insulating layers 110.

When the total thickness variation occurs in the first substrate portion 100, a thickness t1 of a first side surface of the first substrate portion 100 may be thicker than a thickness t2 of a second side surface of the first substrate portion 100. The second side surface of the first substrate portion 100 is a side surface facing the first side surface of the first substrate portion 100. The first substrate portion 100 may have an inclined structure in which the thickness of the first side surface is the thickest and the thickness of the second side surface is the thinnest. In this case, the first substrate portion 100 may have a tendency in which the thickness of the first side surface is thicker than the thickness of the second side surface. The first side surface and the second side surface do not necessarily refer to the outside of the first substrate portion 100, and include that a thickness measured in a first side direction may be greater than a thickness measured in a second side direction. This may denote that upper and/or lower surfaces of the first substrate portion 100 may be inclined in one direction to have an inclined structure.

Although FIG. 4 describes that a thickness variation occurs so that the build-up insulating layers above and below the core insulating layer of the first insulating layer 110 are symmetrical to each other, the present disclosure is not limited thereto, and thickness variations of the build-up insulating layers disposed above and below the core insulating layer may be different from each other. Furthermore, only the build-up insulating layer disposed on an upper surface based on the core insulating layer may have a thickness variation, and this structure may be changed by the design or may be changed by the operation of forming the first insulating layer 110.

In the present disclosure, the thickness of the first substrate portion 100 may denote a distance that vertically crosses upper and lower surfaces of the first substrate portion 100. Since the upper and lower surfaces of the first substrate portion 100 may not form a certain plane by the first wiring layer 120 disposed on an outermost side of the first wiring layer 120, for convenience, the thickness of the first substrate portion 100 may be measured based on the upper and lower surfaces of each of the first insulating layers 110 disposed on the outermost side of the first insulating layer 110, and this analysis may be applied hereinafter.

Since the thickness of the first substrate portion 100 with the total thickness variation may be measured differently depending on the measurement position, it may refer to a vertical distance from any point on the upper surface of the first substrate portion 100 to a point on a lower surface of the first substrate portion 100.

The total thickness variation may be analyzed by measuring a thickness at each point of the first substrate portion 100. For example, in a plan view from the top, the first substrate portion 100 may be divided into a total of 80 areas by dividing the first substrate portion 100 into 10 sections in a horizontal direction and into 8 sections in a vertical direction. Each section may be further divided into nine points at an equal interval. That is, the first substrate portion 100 may be uniformly divided into a total of 720 points. In this case, dividing the first substrate portion 100 may be understood as dividing a thickness measurement area of the first substrate portion 100 using any virtual line or virtual surface, but the present disclosure is not limited thereto, and the dividing may include performing physical cutting.

A thickness distribution of the first substrate portion 100 may be drawn using the thickness measured at each point of the first substrate portion 100, and when the thickness variation at the points corresponding to the first side surface and the second side surface has a variation of about 10 μm as compared to an intermediate value, it may be interpreted that the total thickness variation has occurred. In other words, when a difference between a maximum value of the thickness measured in the first side surface and a minimum value measured in the second side surface is about 20 μm, it may be interpreted that the total thickness variation has occurred.

On the other hand, the above-described measurement method is only an example, and there may be various methods of dividing points, and an absolute value of the variation determining that a thickness variation has occurred may also variously occur. As another example, one section area may be divided to have an arbitrary number of points other than nine points, and one point may be divided to be a square consisting of 1 cm wide and 1 cm long. Furthermore, a range of occurrence of the variation may not be limited to a specific value, but may be determined as a ratio to an intermediate value. That is, the scope of the patent claim is not limited to the measurement method, and any measurement method capable of confirming the occurrence of the thickness variation of the first substrate portion 100 may be used without limitation.

The intermediate insulating layer 250 may be formed on the first substrate portion 100 after forming the first substrate portion 100. That is, the intermediate insulating layer 250 may be disposed on an upper surface of the first insulating layer 110 disposed at an uppermost side among a plurality of first insulating layers 110. The intermediate insulating layer 250 may be formed to bury the first wiring layer 120 disposed on the uppermost side among the plurality of first wiring layers 120.

The intermediate insulating layer 250 may include an insulating material. The insulating material may be a thermosetting resin such as an epoxy resin, a thermoplastic resin such as polyimide, a material in which these insulating resins are mixed with an inorganic filler such as silica, or a resin impregnated with core materials such as glass fibers along with the inorganic filler, for example, an insulating material of Prepreg (PPG), resin coated copper (RCC), but the present disclosure is not limited thereto, and the insulating material may be an Ajinomoto build-up film (ABF), a photo imagable dielectric (PID), FR-4, Bismaleimide Triazine (BT), but the present disclosure is not limited thereto. The intermediate insulating layer 250 may be designed to include an insulating material such as a second insulating layer 210 of the second substrate portion 200 described below, and may have a structure like the second insulating layer 210, and but the present disclosure is not limited thereto.

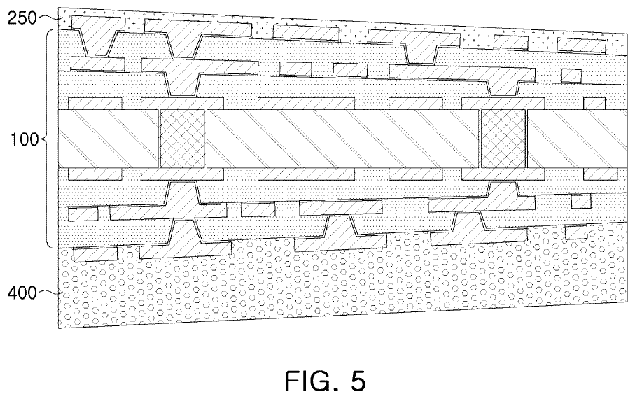

Referring to FIG. 5, a manufacturing method for a printed circuit board according to an example embodiment may include an operation of forming the temporary layer 400 on a surface opposite to a surface on which the intermediate insulating layer 250 of the first substrate portion 100 is formed, after an operation of forming the intermediate insulating layer 250 on the first substrate portion 100.

The temporary layer 400 may correspond to a configuration for adjusting flatness of the first substrate portion 100 and the intermediate insulating layer 250, and may include a metal material, but the present disclosure is not limited thereto, and the temporary layer 400 may include an insulating material.

The metal material may be copper (Cu), aluminum (Al), silver (Ag), tin (Sn), gold (Au), nickel (Ni), lead (Pb), titanium (Ti), or alloys thereof, but may preferably include copper (Cu). When the temporary layer 400 is a metal material, the temporary layer 400 may be formed through plating on the surface opposite to the surface on which the intermediate insulating layer 250 of the first substrate portion 100 is formed. The temporary layer 400 may be formed by electroplating, and if necessary, the temporary layer may be subject to the electroplating after electroless plating. However, the present disclosure is not limited thereto, and the temporary layer 400 may be attached to the first substrate portion 100 in the form of a metal block. In this case, an adhesive means such as an adhesive layer may be used to couple the temporary layer 400 to the first substrate portion 100.

The insulating material may be Prepreg (PPG) or resin coated copper (RCC), but the present disclosure is not limited thereto, and the insulating material may be an Ajinomoto build-up film, a photo imagable device (PID), FR-4, and Bismaleimide Triazine (BT). When the temporary layer 400 includes the insulating material, the temporary layer 400 may be coupled to the first substrate portion 100 using an adhesive means such as an adhesive layer.

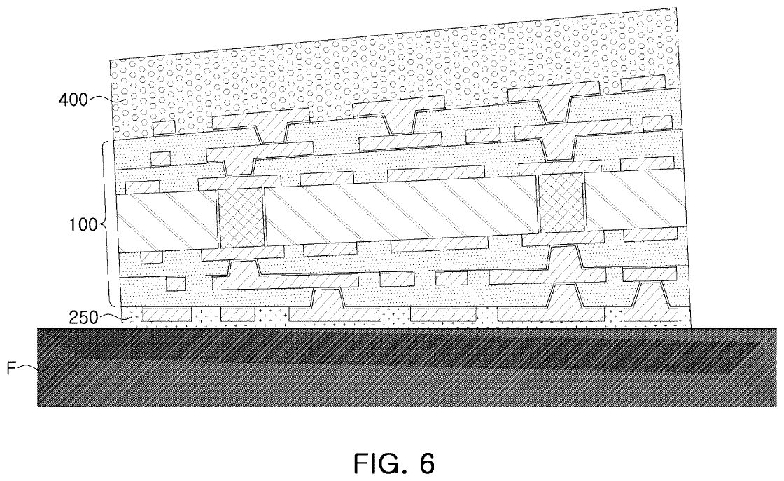

Referring to FIG. 6, a manufacturing method for a printed circuit board according to an example embodiment may include an operation of flattening the temporary layer 400. The operation of flattening the temporary layer 400 may include an operation of inverting the first substrate portion 100 so that the temporary layer 400 is disposed above the first substrate portion 100.

Inverting the first substrate portion 100 may denote arranging the first substrate portion 100 to change upper and lower portions of the first substrate portion 100 with respect to a floor F. That is, it denotes temporarily changing a vertical direction of the first substrate portion 100 during the operation of the manufacturing method for the printed circuit board according to an example, and does not denote a change in the structure of the first substrate portion 100. In other words, the intermediate insulating layer 250 disposed on the first substrate portion 100 may be disposed in a lower portion to face the floor F, and the temporary layer 400 disposed on a surface opposite to a surface of the intermediate insulating layer 250 may be disposed in an upper portion.

In the present disclosure, the floor F may be a virtual surface as a reference surface in the vertical direction of the first substrate portion 100, but may also be an existing surface. The floor F may be understood as a floor disposed in a downward direction of gravity of the first substrate portion 100 and as a general term by denoting a flat surface, perpendicular to the downward direction of gravity. However, the present disclosure is not limited thereto, and the floor F may correspond to one surface of a configuration such as a substrate holder or a substrate support member in a substrate apparatus generally used for a process of a printed circuit board.

Although FIG. 6 describes that the first substrate portion 100 rotates 180 degrees based on a cross-sectional view to invert the first substrate portion 100, the present disclosure is not limited thereto, and the first substrate portion 100 may be inverted by rotating the cross-sectional view of the printed circuit board to be inverted up and down. As illustrated in FIG. 6, in the former case, the first substrate portion 100 rotates 180 degrees with respect to a direction, perpendicular to the cross-sectional view, as a reference axis, and in the latter case, the first substrate portion 100 rotates 180 degrees with respect to a transverse direction of the cross-sectional view as a reference axis.

By inverting the first substrate portion 100, the intermediate insulating layer 250 may be disposed to be substantially parallel to the floor F. The meaning of being substantially parallel is a concept including an approximate one, and may be determined by including, for example, a process error or a position variation occurring in a manufacturing process, and an error during measurement. That is, the fact that an upper surface of the intermediate insulation layer 250 is disposed substantially parallel to the floor denotes that the intermediate insulation layer 250 disposed on the first substrate portion 100 is disposed substantially parallel to the floor F despite the total thickness variation of the first substrate portion 100, which means that a slope generated on one surface of the first substrate portion 100 is overcome and the intermediate insulation layer 250 is disposed to be substantially parallel to the bottom F. However, the present disclosure is not limited thereto, and the fact that the intermediate insulating layer 250 is substantially parallel to the floor F may be a concept that includes the intermediate insulating layer 250 being disposed on the floor F. The intermediate insulating layer 250 being disposed on the floor F may demote that one surface of the intermediate insulating layer 250 is disposed to form the same surface as the floor F.

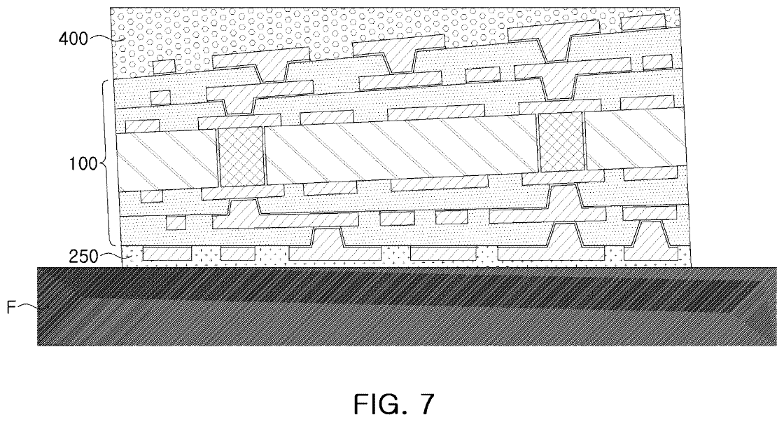

Referring to FIG. 7, a manufacturing method for a printed circuit board according to an example embodiment may include an operation of flattening the temporary layer 400. The step of flattening the temporary layer 400 may include an operation of flattening the temporary layer 400 by removing a portion of the temporary layer 400.

Flattening the temporary layer 400 may denote that a portion of the temporary layer 400 is removed so that one surface of the temporary layer 400 is substantially parallel to the floor F. An operation of removing a portion of the temporary layer 400 may use a process such as cutting and grinding, but the present disclosure is not limited thereto, and any method in which one surface of the temporary layer 400 may be removed to form a certain surface may be used without limitation. That is, any method may be used as long as a lower surface of the temporary layer 400 may be removed to be substantially parallel to the floor. Meanwhile, the operation of removing a portion of the temporary layer 400 may be performed in different ways depending on a material of the temporary layer 400.

In an operation of forming a second substrate portion 200 described below by removing a portion of the temporary layer 400 and flattening the temporary layer 400, the second substrate portion 200 may be formed on a flattened surface of the intermediate insulating layer 250 despite the total thickness variation of the first substrate portion 100.

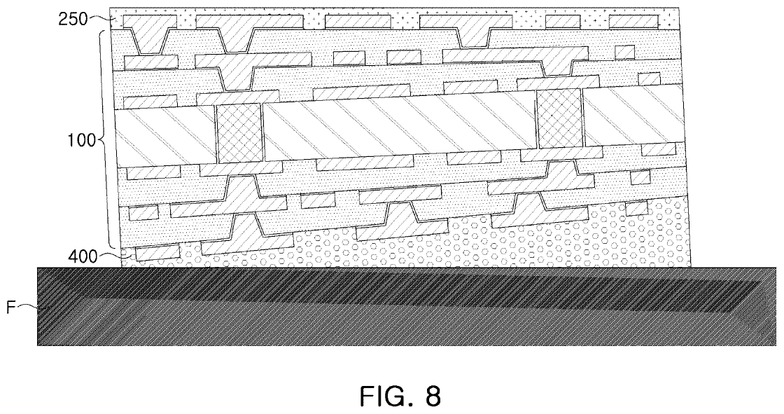

Referring to FIG. 8, a manufacturing method for a printed circuit board according to an example embodiment may include an operation of flattening the temporary layer 400. The operation of flattening the temporary layer 400 may include an operation of inverting the first substrate portion 100 again so that the temporary layer 400 is disposed below the first substrate portion 100.

Inverting the first substrate portion 100 may be interpreted in the same meaning as the above, and inverting the first substrate portion 100 again may denote that the first substrate portion 100 returns to an original direction thereof. That is, the temporary layer 400 may be disposed below the first substrate portion 100, and the intermediate insulating layer 250 may be disposed above the first substrate portion 100.

By inverting the first substrate portion 100 again, the lower surface of the temporary layer 400 may be disposed to be substantially parallel to the floor F. The meaning of being substantially parallel is the same as described above. That is, it may include a meaning that the lower surface of the temporary layer 400 is disposed on the floor. Since the lower surface of the temporary layer 400 may be disposed on the floor after flattening the lower surface of the temporary layer 400, the upper surface of the intermediate insulating layer 250 may be substantially parallel to the floor and disposed above the first substrate portion 100. Accordingly, when the second substrate portion 200 is formed in an operation described below, reliability may be improved.

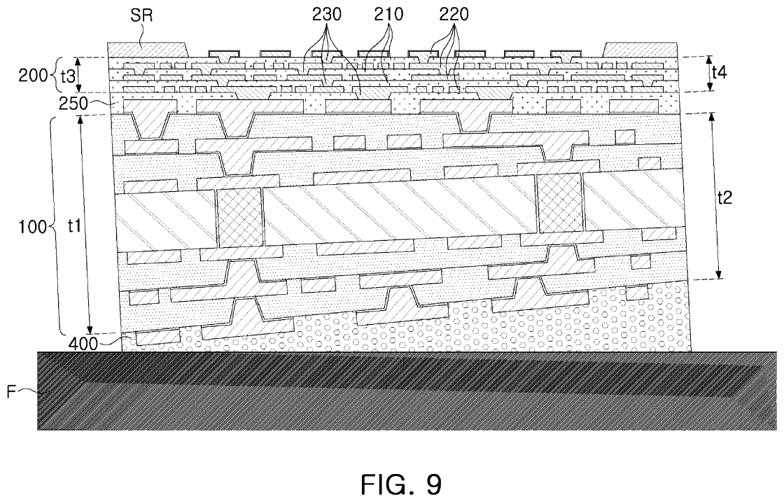

Referring to FIG. 9, a manufacturing method for a printed circuit board according to an example embodiment may include an operation of forming a second substrate portion 200 on an intermediate insulating layer 250. The operation of forming the second substrate portion 200 may include an operation of forming a plurality of second wiring layers 220, a plurality of second insulating layers 210 burying the plurality of second wiring layers 220, and a second via layer 230 penetrating through at least a portion of each of the plurality of second insulating layers 210.

The second insulating layer 210 may include an insulating material. The insulating material may include a thermosetting resin such as an epoxy resin, a thermoplastic resin such as polyimide, or a material including an inorganic filler, an organic filler, and/or glass fibers (e.g., glass fiber, glass cloth, and/or glass fabric) along with these resins, and may be a photosensitive material and/or a non-photosensitive material. For example, the insulating material may be Prepreg (PPG) or resin coated copper (RCC), but the present disclosure is not limited thereto, and insulation materials such as an Ajinomoto build-up film (ABF), a photo imagable dielectric (PID), FR-4, Bismaleimide Triazine (BT), resin coated copper (RCC), copper clad laminate (CC), or photosensitive materials such as a photo imagable dielectric (PID) may be used, but the present disclosure is not limited thereto, and other polymer materials may be included in the insulating material. Meanwhile, when a PID material is used as the second insulating layer 210, it may be easy to finely implement a second wiring layer 220.

The second insulating layer 210 may include the same insulating material as the insulating material of the first insulating layer 110, but the present disclosure is not limited thereto, and these insulating layers may include different materials. Since the second substrate portion 200 implements finer wiring than the first substrate portion 100, the second insulating layer 210 may include an insulating material that is more advantageous for fine processing than the insulating material of the first insulating layer 110. The second insulating layer 210 may include the same insulating material as the insulating material of the intermediate insulating layer 250. However, the present disclosure is not limited thereto, and these insulating layers may include different materials.

The second wiring layer 220 includes a metal material. As the metallic material, copper (Cu), aluminum (Al), silver (Ag), tin (Sn), gold (Au), nickel (Ni), lead (Pb), titanium (Ti), or alloys thereof may be used. Each of the second wiring layers 220 may include an electroless plating layer (or chemical copper) and an electrolytic plating layer (or electrolytic copper), but the present disclosure is not limited thereto. A sputtering layer may be formed instead of chemical copper as the electroless plating layer. If necessary, a copper foil may be further included therein. Each of the second wiring layers 220 may perform various functions according to a design of a corresponding layer. For example, the second wiring layer 220 may include a ground pattern, a power pattern, and a signal pattern. Here, the signal pattern may include various signals such as a data signal, except for the ground pattern and the power pattern. Each of these patterns may include a line pattern, a plane pattern, and/or a pad pattern.

The second via layer 230 may include a micro-via. The micro-via may be a field via filling a via hole or a conformal via disposed along a wall surface of the via hole. The micro-via may be arranged in a stacked type and/or a staggered type. Each of the second via layers 230 may include a metal material, and the metal material may include copper (Cu), aluminum (Al), silver (Ag), tin (Sn), gold (Au), nickel (Ni), lead (Pb), titanium (Ti), or alloys thereof. Each of the second via layers 230 may include an electroless plating layer (or chemical copper) and an electrolytic plating layer (or electrolytic copper), but the present disclosure is not limited thereto. A sputtering layer may be formed instead of chemical copper as the electroless plating layer. A connection via layer may perform various functions according to a design of a corresponding layer. For example, it may include a ground via, a power via, and a signal via. Here, the signal via may include a via for transmitting various signals such as a data signal, except for the ground via and the power via.

Each of the second wiring layer 220 and the second via layer 230 may be integrally formed with each other, but the present disclosure is not limited thereto. The second wiring layer 220 and the second via layer 230 may be formed of any one of a semi additive process (SAP) method, a modified semi additive process (MSAP) method, a tenting (TT) method, or a subtractive method, but the present disclosure is not limited thereto, and any method that can form a circuit on a printed circuit board may be used without limitation.

Meanwhile, a wiring density of the second substrate portion 200 may be higher than a wiring density of the first substrate portion 100. The higher wiring density is a relative concept, and may denote that more circuit patterns may be included in the same area, but the present disclosure is not limited thereto, and the higher wiring density may denote that finer wiring is included. For example, the second wiring layer 220 of the second substrate portion 200 may have a thickness of the wiring, a line/space and a pitch relatively smaller than those of the first wiring layer 120 of the first substrate portion 100. Furthermore, an insulation distance between wirings of the second substrate portion 200 may also be smaller than an insulation distance between wirings of the first substrate portion 100. Meanwhile, the thickness, line, space and pitch may be measured using a scanning microscope or an optical microscope based on a polishing or cutting cross-section of the printed circuit board, and if these values are not constant, an average value of the values measured at any five points may be compared.

In this case, since the second substrate portion 200 implements a relatively fine wiring as compared to the first substrate portion 100, a total thickness variation of the second substrate portion 200 may be minimized. That is, a thickness t3 of the first side surface of the second insulating layer 210 may be substantially the same as a thickness t4 of the second side surface of the second insulating layer 210. In other example, a variation in the thickness t3 of the first side surface of the second insulating layer as compared to the thickness t4 of the second side surface of the second insulating layer 210 may be less than a variation in the thickness t1 of the first side surface of the first substrate portion 100 as compared to the thickness t2 of the second side surface of the first substrate portion 100. The second side surface of the second insulating layer 210 is a side surface facing the first side surface of the second insulating layer 210. That is, the second substrate portion 200 may be formed to have a substantially uniform thickness. The meaning of being substantially the same is a concept including an approximate one, and may be determined by including, for example, a process error or a position variation occurring in a manufacturing process, and an error during measurement. The thickness of the second insulating layer 210 may be measured using a scanning microscope or an optical microscope based on a polishing or cutting cross-section, and if these values are not constant, an average value of the values measured at any five points may be compared.

Before forming the second substrate portion 200, the flattening may be performed by adjusting a slope of the first substrate portion 100 and a slope of the intermediate insulating layer 250 using the temporary layer 400, and accordingly, the second substrate portion 200 may be formed in a state in which the first substrate portion 100 and the intermediate insulating layer 250 are disposed in substantial parallel with the floor. Accordingly, despite the total thickness variation occurring in the first insulating layer 110, the second substrate portion 200 including a microcircuit may be stably formed.

Meanwhile, FIG. 9 illustrates, after the operation of forming the second substrate portion 200, further including an operation of forming a solder resist layer SR on the second substrate portion 200, but the present disclosure is not limited thereto.

The solder resist layer SR may protect the printed circuit board from the outside. The solder resist layer SR may include a thermosetting resin and an inorganic filler dispersed in the thermosetting resin, but may not include glass fibers. The insulating resin may be a photosensitive insulating resin, and the filler may be an inorganic filler and/or an organic filler, but is not limited thereto. However, a material of the solder resist layer SR is not limited thereto, and other polymer materials may be used as necessary. The solder resist layer SR may include an opening, and a portion of the second wiring layer 220 disposed on an outermost side may be exposed to the outside through the opening. The second wiring layer 220 exposed to the outside through the opening of the solder resist layer SR may function as a pad for mounting electronic components on a printed circuit board.

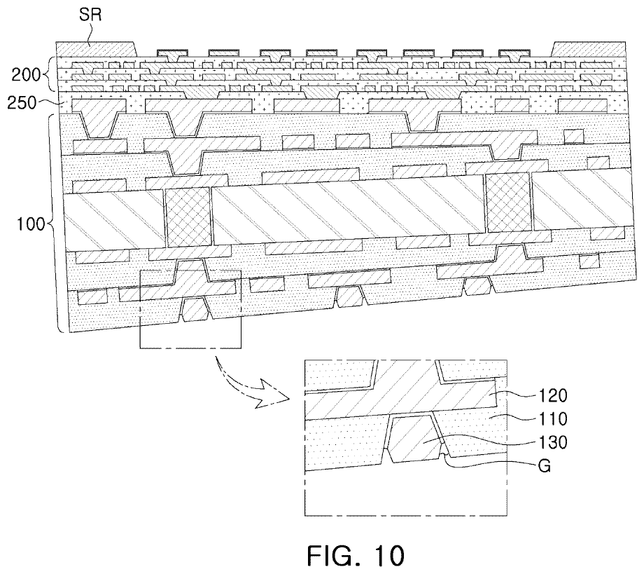

Referring to FIG. 10, a manufacturing method for a printed circuit board according to an example embodiment may include an operation of removing the temporary layer 400 after forming the second substrate portion 200.

The operation of removing the temporary layer 400 may be performed using at least one of a chemical-mechanical polishing (CMP) process and an etching process, but the present disclosure is not limited thereto.

In the case of using the chemical-mechanical polishing (CMP) process as the operation of removing the temporary layer 400, a portion of the first wiring layer 120 disposed lowermost, may be removed and a portion of the first via layer 130 disposed lowermost may be exposed to the outside. The chemical-mechanical polishing (CMP) process may be advanced simultaneously with chemical polishing using a chemical composition and mechanical polishing using a polishing pad, and accordingly, in the case of removing the temporary layer 400 through the chemical-mechanical polishing (CMP) process, the first wiring layer 120 disposed lowermost may be removed and a portion of the first via layer 130 disposed lowermost may be removed at the same time.

Specifically, since the chemical-mechanical polishing (CMP) process uses the chemical composition, at least a portion of an external circumferential surface of the first via layer 130 disposed lowermost may be further removed to form a gap region G for separating the first via layer 130 disposed lowermost from the first insulating layer 110 disposed lowermost. That is, the gap region G may correspond to a trace from which a portion of the first via layer 130 disposed lowermost is removed. In particular, as described above, since chemical polishing using a chemical composition may be performed in the chemical-mechanical polishing (CMP) process, the gap region G may be formed along an external circumferential surface of a lower surface of the first via layer 130 disposed lowermost.

On the other hand, although not illustrated in FIG. 10, the present disclosure is not limited to the gap region G, and a lower surface of the first via layer 130 disposed lowermost may have a groove portion partially recessed. Similarly to the gap region G, the groove portion may also correspond to a trace from which a portion of the first via layer 130 disposed lowermost is removed. As the groove portion is generated on the lower surface of the first via layer 130 disposed lowermost, the lower surface of the first via layer 130 disposed lowermost may have an uneven surface rather than a flat surface.

On the other hand, although not illustrated in FIG. 10, when the chemical-mechanical polishing (CMP) process is used in the operation of removing the temporary layer 400, a portion of the first insulating layer 110 disposed lowermost may also be removed. When a portion of the first insulating layer 110 disposed lowermost is removed, the lower surface of the first substrate portion 100 may have a flat surface, but the present disclosure is not limited thereto. Since the first substrate portion 100 includes a wiring having a less density than a wiring of the second substrate portion 200, the lower surface of the first substrate portion 100 may have less effect on the reliability of the printed circuit board even if it does not have a flat surface. This will be described below in more detail.

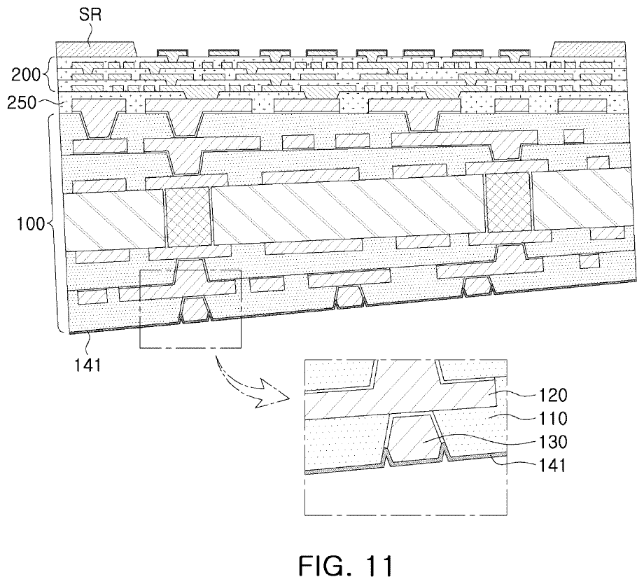

Referring to FIG. 11, a manufacturing method for a printed circuit board according to an example embodiment may further include an operation of forming a first metal layer 141 on at least a portion of a first insulating layer disposed lowermost, after the operation of removing the temporary layer 400. The first metal layer 141 may function as a seed layer in the operation of forming a second metal layer 142 described below.

The first metal layer 141 may include a metal material, and the metal material may include copper (Cu), aluminum (Al), silver (Ag), tin (Sn), gold (Au), nickel (Ni), lead (Pb), titanium (Ti), or alloys. The first metal layer 141 may function as a seed layer for plating the second metal layer 142 described below, and may be formed by performing an electroless plating process, but the present disclosure is not limited thereto, and the first metal layer 141 may be formed by performing a sputtering process.

The first metal layer 141 may be formed on the lower portion of the first substrate portion 100 and may be formed along the lower surface of the first insulating layer 110 disposed lowermost and the lower surface of the first via layer 130 disposed lowermost. The first metal layer 141 may be formed to extend from the first insulating layer 110 disposed lowermost to the first via layer 130 disposed lowermost. In this case, the first metal layer 141 may be formed to fill the gap region G for separating the first insulating layer 110 disposed at the bottom from the first via layer 130 disposed lowermost.

Since the first metal layer 141 may be formed along the first insulating layer 110 disposed lowermost, the total thickness variation occurring in the first substrate portion 100 may be applied. In other words, the lower surface of the first insulating layer 110 disposed lowermost may have a slope due to the total thickness variation of the first substrate portion 100, and the first metal layer 141 may also have the same slope as the lower surface of the first insulating layer 110 disposed lowermost.

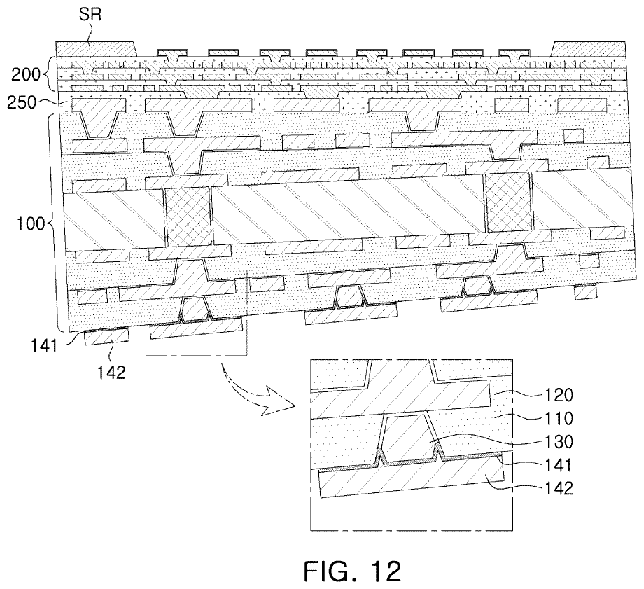

Referring to FIG. 12, a manufacturing method for a printed circuit board according to an example embodiment may include an operation of forming the second metal layer 142 on the first metal layer 141, after the operation of forming the first metal layer 141.

The second metal layer 142 may include a metal material, and the metal material may be copper (Cu), aluminum (Al), silver (Ag), tin (Sn), gold (Au), nickel (Ni), lead (Pb), titanium (Ti), or alloys thereof. The second metal layer 142 may include the same metal material as the first metal layer 141, but the present disclosure is not limited thereto, and these metal layers may include different metal materials.

The operation of forming the second metal layer 142 may be performed by a plating process using the first metal layer 141 as a seed layer. Specifically, the operation of forming the second metal layer 142 may include an operation of forming the second metal layer 142 on the first metal layer 141, an operation of patterning the second metal layer 142, and an operation of removing a portion of the first metal layer 141, but some processes may be omitted or added as necessary. The second metal layer 142 may be formed by any one of a semi additive process (SAP) method, a modified semi additive process (MSAP) method, a Tenting (TT) method, or a subtractive method, but the present disclosure is not limited thereto, and any method that can form a circuit on a printed circuit board may be used without limitation. After forming the second metal layer 142, a portion of the first metal layer 141 may be removed to complete an electrical signal path.

Since the first metal layer 141 may have a slope, the second metal layer 142 may also have the same slope as that of the first metal layer 141. That is, the total thickness variation occurring in the first substrate portion 100 may also affect the second metal layer 142. However, since the first wiring layer 120 and the first and second metal layers 141 and 142 correspond to relatively less fine wirings than the second wiring layer 220 of the second substrate portion 200, even if the first wiring layer 120 and the first and second metal layers 141 and 142 have a slope, they may be more advantageous in securing reliability than in a structure in which the second wiring layer 220 of the second substrate portion 200 has a slope.

Since the second substrate portion 200 implementing a fine wiring is more vulnerable to the total thickness variation of the first substrate portion 100, the structure in which the second wiring layer 220 has a slope may be more disadvantageous than the structure in which the first wiring layer 120 and the first and the second metal layers 141 and 142 have a slop. Accordingly, even if the first metal layer 141 and the second metal layer 142 have a slope, the slope may be insignificant, so that the effect on the reliability of the printed circuit board according to an example embodiment may not be significant. Accordingly, the manufacturing method for a printed circuit board according to an example embodiment is meant to perform an operation of implementing the flattening by introducing the temporary layer 400 to minimize a thickness deviation of a surface on which the second substrate portion 200 is formed, among the total thickness variation occurring in the first substrate portion 100, from which the second substrate portion 200 with a fine wiring implemented therein may be formed on a flat surface despite the total thickness variation of the first substrate portion 100.

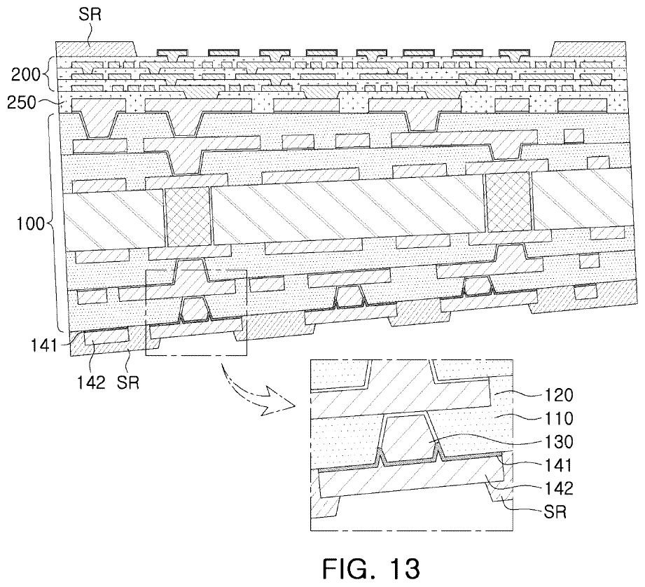

Referring to FIG. 13, a manufacturing method for a printed circuit board according to an example embodiment may further include an operation of forming a solder resist layer SR, after the operation of forming the second metal layer 142.

The solder resist layer SR may protect the printed circuit board from the outside. The solder resist layer SR may include a thermosetting resin and an inorganic filler dispersed in the thermosetting resin, but may not include glass fibers. The insulating resin may be a photosensitive insulating resin, and the filler may be an inorganic filler and/or an organic filler, but is not limited thereto. However, a material of the solder resist layer SR is not limited thereto, and other polymer materials may be used as necessary. The solder resist layer SR may include an opening, and a portion of the second metal layer 142 may be exposed to the outside through the opening. The second metal layer 142 exposed to the outside through the opening of the solder resist layer SR may function as a pad for mounting a printed circuit board on a main board, or a pad for mounting electronic components on the printed circuit board.

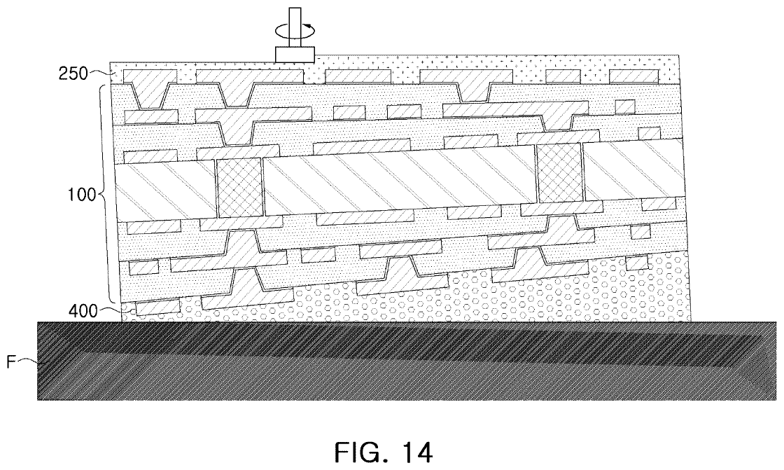

FIG. 14 is a cross-sectional view schematically illustrating a portion of a manufacturing method for a printed circuit board according to another example embodiment.

Referring to FIG. 14, a manufacturing method for a printed circuit board according to another example embodiment may further include an operation of flattening the intermediate insulating layer 250, before forming the second substrate portion 200.

The operation of flattening the intermediate insulating layer 250 may include an operation of removing a portion of an upper surface of the intermediate insulating layer 250, and may use processes such as cutting and grinding, but the present disclosure is not limited thereto, and any method in which the upper surface of the intermediate insulating layer 250 may be removed to form a certain plane may be used without limitation.

In the operation of flattening the intermediate insulating layer 250, a rough surface having a large roughness may occur on the upper surface of the intermediate insulating layer 250. That is, the upper surface of the intermediate insulating layer 250 may be formed to have a greater roughness than that of an upper surface of at least one first insulating layer 110 among a plurality of first insulating layers 110, and the upper surface of the intermediate insulating layer 250 may be formed to have a greater roughness than that of an upper surface of at least one second insulating layer 210 among a plurality of second insulating layers.

When the second substrate portion 200 including the fine wiring is formed immediately on the first substrate portion 100 in which the total thickness variation has occurred, as described above, there may be a high risk of problems such as misalignment of the second wiring layer 220 of the second substrate portion 200. Accordingly, before forming the second substrate portion 200, the intermediate insulating layer 250 may be formed and flatten, thus securing the reliability of the second substrate portion 200.

However, in the case of flattening the intermediate insulating layer 250 disposed on the first substrate portion 100 in which the total thickness variation has occurred, when the upper surface of the intermediate insulation layer 250 is flattened by means of a method for removing a portion of the intermediate insulation layer 250, the first wiring layer 120 in contact with the intermediate insulation layer 250 and disposed at an uppermost side may be damaged. In other words, in a case in which a degree of the total thickness variation occurring in the first substrate portion 100 is large and a thickness of one side surface of the first substrate portion 100 is formed larger than the sum of a thickness of the other side surface and a thickness of the intermediate insulating layer 250, when flattening the intermediate insulating layer 250, there may be a problem in that a portion of the first wiring layer 120 disposed at an outermost side may be removed.

Accordingly, when the intermediate insulation layer 250 is flattened after the upper surface of the first insulation layer 110 of the first substrate portion 100 in which the total thickness variation occurred is disposed to be flat using the temporary layer 400, there is no risk of damage to the first wiring layer 120, and since the flattening process is performed after the intermediate insulation layer 250 has a flat surface first using the temporary layer 400, the flat surface may be implemented more finely in the intermediate insulation layer 250. Accordingly, even if the total thickness variation occurs in the first substrate portion 100 so that the thickness of one side surface of the first substrate portion 100 is larger than the sum of the thickness of the other side surface and the thickness of the intermediate insulating layer 250, the intermediate insulating layer 250 may be flattened.

Among other operations, the same operation as a manufacturing method for a printed circuit board according to an example embodiment may be applied to a manufacturing method for a printed circuit board according to another example embodiment, and thus redundant descriptions thereof will be omitted.

Referring to FIG. 15, a manufacturing method for a printed circuit board according to another example embodiment may further include an operation of forming a third substrate portion 300, after the operation of forming the second metal layer 142. The operation of forming the third substrate portion 300 may include an operation of forming a third insulating layer 310, a third wiring layer 320 formed on the third insulating layer 310, and a third via layer 330 penetrating through at least a portion of the third insulating layer 310 to be connected to the third wiring layer 320. The third substrate portion 300 may be formed on a surface opposite to a surface on which the second substrate portion 200 of the first substrate portion 100 is formed, and the third insulating layer 310 of the third substrate portion 300 may bury the second metal layer 142.

The third insulating layer 310 may include an insulating material, and may include the same insulating material as the first insulating layer 110 and/or the second insulating layer 210, but the present disclosure is not limited thereto, and the third insulating layer 310 may include an insulating material different from the insulating material of the first insulating layer 110 and the second insulating layer. The insulating material may be Prepreg (PPG) or resin coated copper (RCC), but the present disclosure is not limited thereto, and the insulating material may be an Ajinomoto build-up film (ABF), a photo imagable dielectric (PID), FR-4, and Bismaleimide Triazine (BT). However, the present disclosure is not limited thereto, and if necessary, other polymer materials with excellent rigidity may be used.

The third wiring layer 320 may include a metal material. As the metal material, copper (Cu), aluminum (Al), silver (Ag), tin (Sn), gold (Au), nickel (Ni), lead (Pb), titanium (Ti), or alloys thereof may be used. Each of the third wiring layers 320 may include an electroless plating layer (or chemical copper) as a seed layer and an electrolytic plating layer (or electric copper) as a plating layer, but the present disclosure is not limited thereto. A sputtering layer may be formed instead of chemical copper as the electroless plating layer. If necessary, a copper foil may be further included. Each of the third wiring layers 320 may perform various functions according to a design of a corresponding layer. For example, the third wiring layer 320 may include a ground pattern, a power pattern, and a signal pattern. Here, the signal pattern may include various signals such as a data signal, except for the ground pattern and the power pattern. Each of these patterns may include a line pattern, a plane pattern, and/or a pad pattern.

The third via layer 330 may include a micro-via. The micro-via may be a field via filling the via hole or a conformal via disposed along a wall surface of the via hole. The micro-via may be disposed in a stacked type and/or a stacked type. Each of the connection via layers may include a metal material, and the metal material may include copper (Cu), aluminum (Al), silver (Ag), tin (Sn), gold (Au), nickel (Ni), lead (Pb), titanium (Ti), or alloys thereof. Each of the third via layers 330 may include an electroless plating layer (or chemical copper) as a seed layer and an electrolytic plating layer (or electric copper) as a plating layer, but the present disclosure is not limited thereto. A sputtering layer may be formed instead of chemical copper as the electroless plating layer. The third via layer 330 may perform various functions according to the design of the corresponding layer. For example, the third via layer 330 may include a ground via, a power via, and a signal via. Here, the signal via may include a via for transmitting various signals such as a data signal, except for the ground via and the power via.

The third wiring layer 320 and the third via layer 330 may be integrally formed, but the present disclosure is not limited thereto. The third wiring layer 320 and the third via layer 330 may be formed by any one of a semi additive process (SAP) method, a modified semi additive process (MSAP) method, a Tenting (TT) method, or a subtractive method, but the present disclosure is not limited thereto, and any method that can form a circuit on a printed circuit board may be used without limitation.

The third substrate portion 300 may be formed in the first substrate portion 100 to correspond to the second substrate portion 200, which does not mean that the third substrate portion 300 is formed in the same manner to be symmetrical to the second substrate portion 200, but may mean that the third substrate portion 300 may be formed in an opposite direction of the second substrate portion 200. As the third substrate portion 300 is formed in the opposite direction of the second substrate portion 200, reliability may be secured, such as supplementing bending rigidity of the printed circuit board.

Since the third substrate portion 300 is formed below the first substrate portion 100, the third substrate portion 300 may have a slope due to the total thickness variation occurring in the first substrate portion 100. Meanwhile, the third wiring layer 320 of the third substrate portion 300 corresponds to a relatively less fine wiring than the second wiring layer 220 of the second substrate portion 200. Accordingly, even if the third wiring layer 320 of the third substrate portion 300 has the slope, it may be more advantageous in securing reliability than in a structure in which the second wiring layer 220 of the second substrate portion 200 has a slope.

On the other hand, although not illustrated in FIG. 15, after forming the third insulating layer 310 of the third substrate portion 300, the method may further include an operation of flattening a lower surface of the third insulating layer 310. That is, after flattening the third insulating layer 310, the third wiring layer 320 may be formed. The operation of flattening the lower surface of the third insulating layer 310 may use the same process as the operation of flattening the intermediate insulating layer 250. After the third insulating layer 310 is formed below the first substrate portion 100, when the third insulating layer 310 is flattened, the third wiring layer 320 may be disposed in substantial parallel with the second wiring layer 220 of the second substrate portion 200.

On the other hand, in FIG. 15, the third insulating layer 310 of the third substrate portion 300 is illustrated as one third insulating layer 310, but the present disclosure is not limited thereto, and the number of layers of the third substrate portion 300 may be changed according to the design of the printed circuit board.

Meanwhile, after forming the third substrate portion 300, the method may further include an operation of forming a solder resist layer SR below the third substrate portion 300. The aforementioned description in the manufacturing method for a printed circuit board according to an example embodiment may be identically applied to the operation of forming the solder resist layer SR.

Among other operations, the same operation as a manufacturing method for a printed circuit board according to an example embodiment and a manufacturing method for a printed circuit board according to the other example embodiments may be applied to a manufacturing method for a printed circuit board according to another example embodiment, and thus redundant descriptions thereof will be omitted.

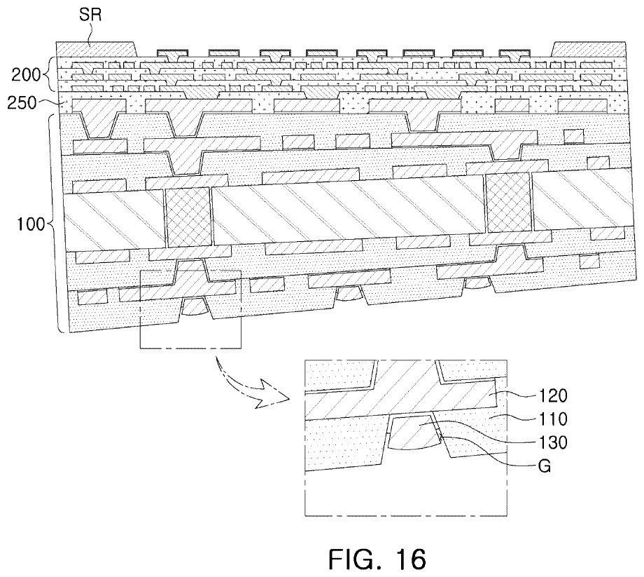

FIGS. 16 to 18 are cross-sectional views schematically illustrating a portion of a manufacturing method for a printed circuit board according to another example embodiment.

Referring to FIG. 16, an operation of removing the temporary layer 400 in a manufacturing method for a printed circuit board according to another example embodiment may be performed using an etching process.

In the case of using the etching process as a step of removing the temporary layer 400, at least a portion of a lower surface of the first wiring layer 120 disposed lowermost of the first wiring layer 120 may be removed, and at least a portion of the lower surface of the first via layer 130 disposed lowermost may be exposed to the outside. A wet etching may be used as the etching, but the present disclosure is not limited thereto, and a dry etching may also be used.

Meanwhile, unlike using a chemical-mechanical polishing (CMP) process in the operation of removing the temporary layer 400, in the case of using an etching process, a portion of the first via layer 130 disposed lowermost may be further removed. In other words, a portion of the first via layer 130 disposed lowermost may be removed so that a lower surface of at least one first via of the first via layer 130 disposed lowermost is disposed inside the first insulating layer 110 disposed lowermost, and a lower surface of the first via layer 130 disposed lowermost and a lower surface of the first insulating layer 110 disposed lowermost may have mutual step portions. Meanwhile, although not illustrated in FIG. 16, when the temporary layer 400 is removed by the etching, since a degree of etching the via may vary depending on an etching condition and a location of the via, each via of the first via layer 130 disposed lowermost may have different depths. This is because a via adjacent to a portion in which the temporary layer 400 is formed thin is further removed than a via adjacent to a portion in which the temporary layer 400 is formed thick.

Even if the temporary layer 400 is removed by the etching, at least a portion of an external circumferential surface of the first via layer 130 disposed lowermost may be removed to form a gap region G for separating the first insulating layer 110 disposed lowermost from the first via layer 130 disposed lowermost. That is, the gap region G may correspond to a trace from which the first via layer 130 disposed lowermost is removed, and in particular, when the wet etching is performed, the gap region G may be formed along the external circumferential surface of the lower surface of the first via layer 130 disposed lowermost.

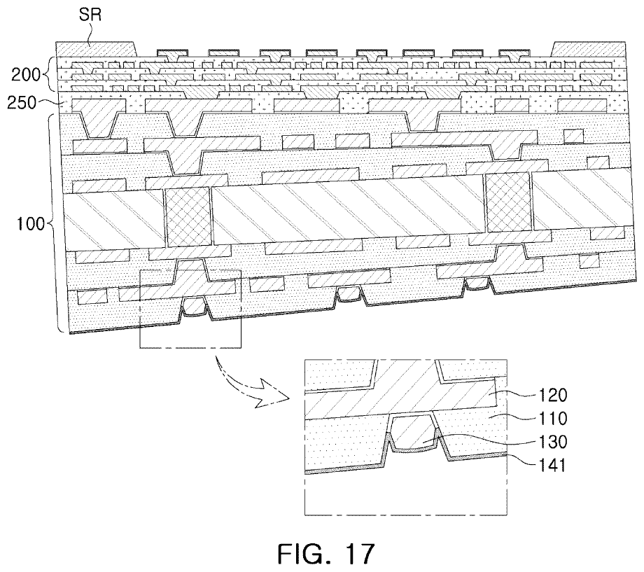

Referring to FIG. 17, a manufacturing method for a printed circuit board according to another example embodiment may further include an operation of forming a first metal layer 141 on at least a portion of a first insulating layer disposed lowermost, after removing the temporary layer 400. The first metal layer 141 may function as a seed layer in an operation of forming a second metal layer 142 described below.

The operation of forming the first metal layer 141 may be the same as the manufacturing method for a printed circuit board according to an example embodiment. However, in the operation of removing the temporary layer 400, a lower surface of the first via layer 130 disposed lowermost and a lower surface of the first insulating layer 110 disposed lowermost may have mutual step portions using the etching process, and accordingly, the first metal layer 141 formed along a boundary between the first via layer 130 disposed lowermost and the first insulating layer 110 disposed lowermost may have a step portion.

The first metal layer 141 may be formed to extend along the boundary between the first insulating layer 110 disposed lowermost and the first via layer 130 disposed lowermost, which is the same content as described in the manufacturing method for a printed circuit board according to an example embodiment, and the first metal layer 141 may be formed to fill the gap region G, which is the same content as described above.

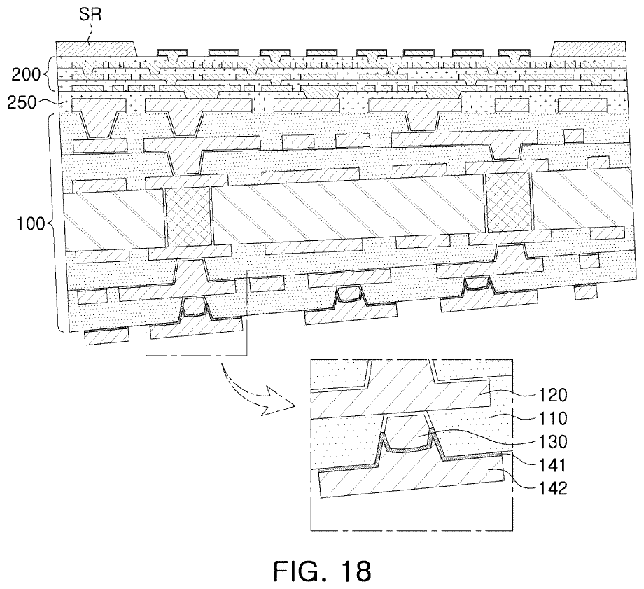

Referring to FIG. 18, a manufacturing method for a printed circuit board according to an example may include an operation of forming the second metal layer 142 on the first metal layer 141, after forming the first metal layer 141.

The operation of forming the second metal layer 142 may be performed in the same manner as the manufacturing method for a printed circuit board according to an example embodiment. Because the second metal layer 142 extends to the lower surface of the first insulating layer 110 disposed lowermost while filling all regions in which the first via layer 130 disposed lowermost and the first wiring layer 120 disposed lowermost were present, when a relatively large amount of the first via is removed in the operation of removing the temporary layer 400, a relatively large amount of the second metal layer 142 may be formed.

Among other operations, the same operation as a manufacturing method for a printed circuit board according to an example embodiment and a manufacturing method for a printed circuit board according to the other example embodiments may be applied to a manufacturing method for a printed circuit board according to another example embodiment, and thus redundant descriptions thereof will be omitted.

### Printed Circuit Board

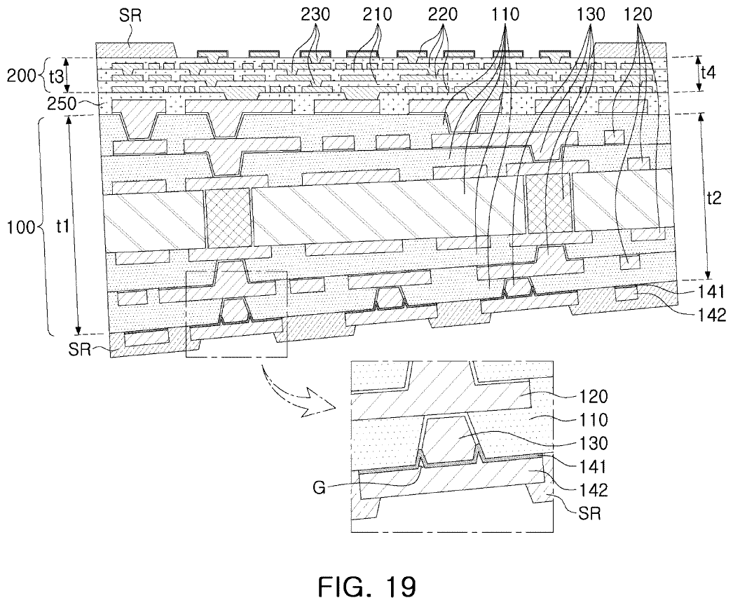

FIG. 19 is a cross-sectional view schematically illustrating a printed circuit board according to another example embodiment.

Referring to FIG. 19, a printed circuit board according to an example embodiment may include a first substrate portion 100 including a plurality of first insulating layers 110, a plurality of first wiring layers 120 respectively disposed on or in the plurality of first insulating layers 110, and a plurality of first via layers 130 penetrating through at least a portion of each of the plurality of first insulating layers 110, a second substrate portion 200 disposed on the first substrate portion 100, and an intermediate insulating layer 250 disposed between the first substrate portion 100 and the second substrate portion 200, and the first substrate portion 100 may include a gap region G for separating at least one portion of at least one first via of the first via layer 130 disposed lowermost, among the plurality of first via layers 130, from the first insulating layer 110 disposed lowermost among the plurality of first insulating layers 110.

The printed circuit board according to an example embodiment may include a gap region G for separating a portion of at least one first via of the first via layer 130 disposed lowermost from the first insulating layer 110 disposed lowermost. The gap region G may correspond to a trace from which a portion of the first via is removed in the manufacturing method for a printed circuit board according to an example embodiment. As described above, the manufacturing method for a printed circuit board according to an example embodiment may use a chemical-mechanical polishing (CMP) process in the operation of removing the temporary layer 400, and accordingly, a portion of the first via of the first via layer 130 disposed lowermost may be removed, thus generating the gap region G.

The first wiring layer 120 disposed lowermost of the printed circuit board according to an example embodiment may include a first metal layer 141 and a second metal layer 142. The first metal layer 141 may function as a seed layer for plating the second metal layer 142, but the present disclosure is not limited thereto. The first metal layer 141 may be disposed to extend along a lower surface of the first via and a lower surface of the first insulating layer 110 disposed lowermost, and may be disposed to fill the gap region G.

A total thickness variation may occur in the first substrate portion 100 of the printed circuit board according to an example embodiment, as described above in the manufacturing method for a printed circuit board according to an example embodiment. That is, the total thickness deviation of the first substrate portion 100 may occur, a thickness t1 of a first side surface of the first substrate portion 100 may be greater than a thickness t2 of a second side surface facing the first side surface, and the first substrate portion 100 may have an inclined structure such that the thickness t1 of the first side surface is the thickest and the thickness t2 of the second side surface is the thinnest. On the other hand, a thickness t3 of a first side surface of the second substrate portion 200 may be substantially the same as a thickness t4 of a second side surface facing the first side surface. Despite the total thickness variation of the first substrate portion 100, the second substrate portion 200 may be disposed on the flattened intermediate insulating layer 250. Because the second substrate portion 200 may include a wiring finer than a wiring of the first substrate portion 100, the second substrate portion 200 may have little total thickness variation.

On the other hand, explanations other than the configuration of the printed circuit board according to an example embodiment may be applied in the same manner as described above in a manufacturing method for a printed circuit board according to an example embodiment, and thus redundant descriptions thereof will be omitted.

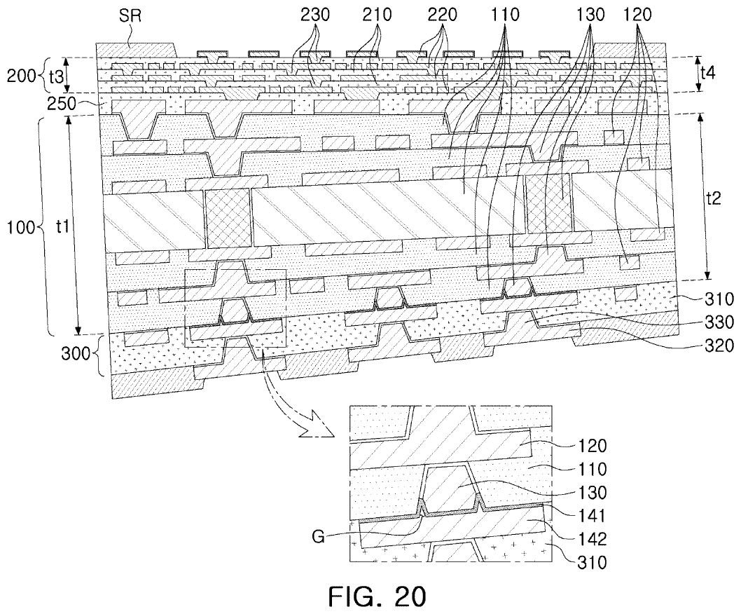

FIG. 20 is a cross-sectional view schematically illustrating a printed circuit board according to another example embodiment.

Referring to FIG. 20, a printed circuit board according to another example embodiment may further include a third insulating layer 310, a third wiring layer 320 disposed on the third insulating layer, and a third via layer 330 penetrating through at least a portion of the third insulating layer to be connected to the third wiring layer 320. The third substrate portion 300 may be disposed below a lower surface of the first substrate portion 100. Specifically, the third substrate portion 300 may be disposed on a side opposite to a side on which the second substrate portion 200 of the first substrate portion 100 is formed. The third insulating layer 310 of the third substrate portion 300 may be disposed below the lower surface of the first insulating layer 110, and the third wiring layer 320 may be disposed below a lower surface of the third insulating layer 310. The third via layer 330 may penetrate through the third insulating layer 310 to connect the third wiring layer 320 to the second metal layer 142 which is the first wiring layer disposed lowermost.

A printed circuit board according to another example embodiment may have an advantageous effect on physical properties such as securing bending rigidity of the printed circuit board as the third substrate portion 300 is further disposed at a position symmetrical to the second substrate portion 200.

Specifically, a printed circuit board according to another example embodiment may have a structure in which the third insulating layer 310 of the third substrate portion 300 buries the first metal layer 141 and the second metal layer 142 because the third substrate portion 300 is disposed after forming the first metal 141 and the second metal layer 142, after removing the temporary layer 400. In other words, the first metal layer 141 and the second metal layer 142 disposed at an outermost side of the first substrate portion 100 are not limited to being disposed at an outermost side of the printed circuit board, and the first metal layer 141 and the second metal layer 142 of the first substrate portion 100 may function as another build-up wiring layer by the third substrate portion 300 further disposed below the first substrate portion 100.

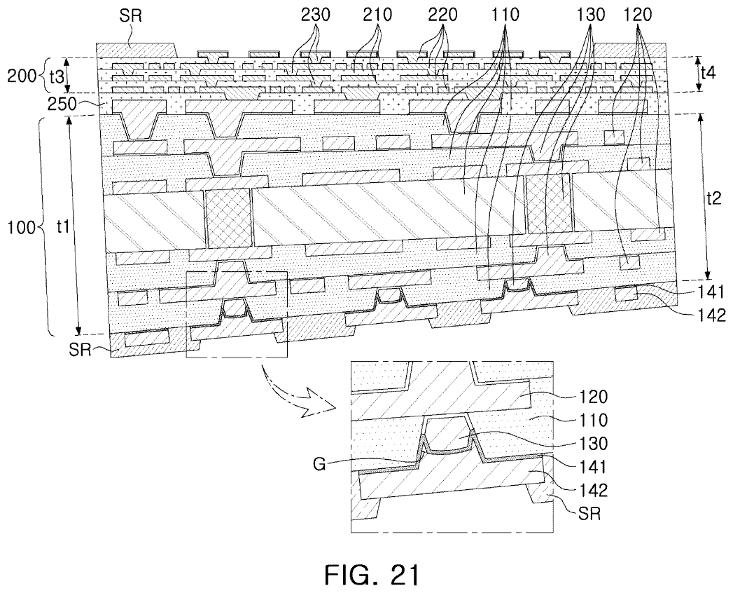

On the other hand, explanations other than the configuration of the printed circuit board according to another example embodiment may be applied in the same manner as described above in a printed circuit board according to an example embodiment, a manufacturing method for a printed circuit board according to an example embodiment, and a manufacturing method for a printed circuit board according to another example embodiment, and thus redundant descriptions thereof will be omitted. FIG. 21 is a cross-sectional view schematically illustrating a printed circuit board according to another example embodiment.

Referring to FIG. 21, in a printed circuit board according to another example embodiment, a boundary surface between at least one first via of the first via layer 130 disposed lowermost, and the first metal layer 141 may be disposed inside the first insulating layer 110 disposed lowermost, and the boundary surface between the first via and the first metal layer 141 and the lower surface of the first insulating layer 110 disposed lowermost may have a step portion.

This corresponds to a result of using the etching process in the operation of removing the temporary layer 400 of the manufacturing method for a printed circuit board according to another example embodiment. In other words, the first via layer 130 disposed lowermost may be removed relatively more than in the case of the printed circuit board according to an example embodiment, so that the lower surface of at least one first via of the first via layer 130 disposed lowermost may be disposed in the first insulating layer 110 disposed lowermost. If the etching process is used in the operation of removing the temporary layer 400, a portion of the first via layer 130 disposed lowermost may be removed more than in the case of using the chemical-mechanical polishing (CMP) process. Since more portions of the first via layer 130 disposed lowermost have been removed, the gap region G of the printed circuit board according to another example embodiment may be formed deeper than a gap region of the printed circuit board according to an example embodiment.

Furthermore, as more portions of the first via layer 130 disposed lowermost is removed, the lower surface of at least one first via of the first via layer 130 disposed lowermost may have a step difference from the lower surface of the first insulating layer 110 disposed lowermost. In a printed circuit board according to another example embodiment, the first metal layer 141 and the second metal layer 142 may be further disposed to fill a portion from which the first via is removed, which is the same as the printed circuit board according to an example embodiment.

On the other hand, explanations other than the configuration of the printed circuit board according to another example embodiment may be applied in the same manner as described above in a printed circuit board according to an example embodiment, a manufacturing method for a printed circuit board according to an example embodiment, a printed circuit board according to another example embodiment, and a manufacturing method for a printed circuit board according to another example embodiment, and thus redundant descriptions thereof will be omitted.

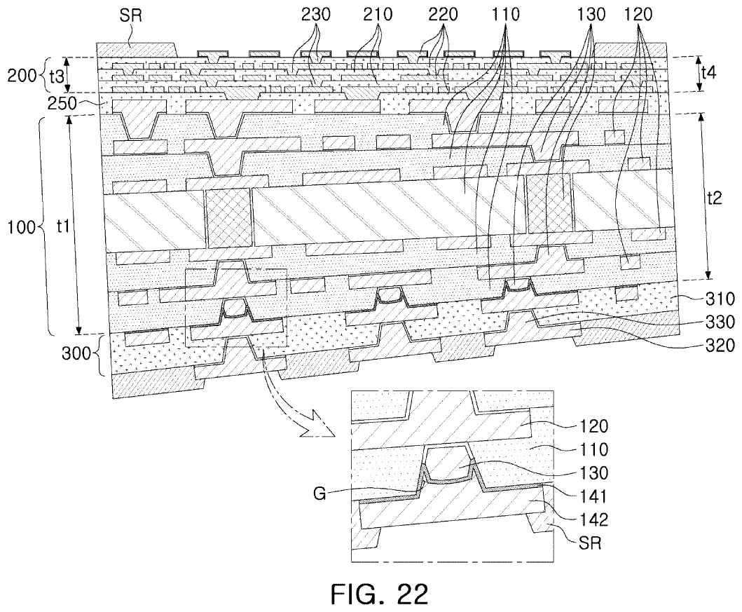

FIG. 22 is a cross-sectional view schematically illustrating a printed circuit board according to another example embodiment.

Referring to FIG. 22, in a printed circuit board according to another example embodiment, a lower surface of at least one first via of the first via layer 130 disposed lowermost may be disposed at a lower surface of the first insulating layer 110 disposed lowermost, and the third substrate portion 300 may be further included in a surface opposite to the surface on which the second substrate portion 200 of the first substrate part 100 is formed. This corresponds to a result of using the etching process in the operation of removing the temporary layer 400 in the manufacturing method for a printed circuit board according to another example embodiment, and corresponds to a result of further including the operation of forming the third substrate portion 300 after the operation of forming the second metal layer 142.

On the other hand, explanations other than the configuration of the printed circuit board according to another example embodiment may be applied in the same manner as described above in a printed circuit board according to an example embodiment, a manufacturing method for a printed circuit board according to an example embodiment, a printed circuit board according to another example embodiment, and a manufacturing method for a printed circuit board according to another example embodiment, and thus redundant descriptions thereof will be omitted.

### Manufacturing Method for Printed Circuit Board

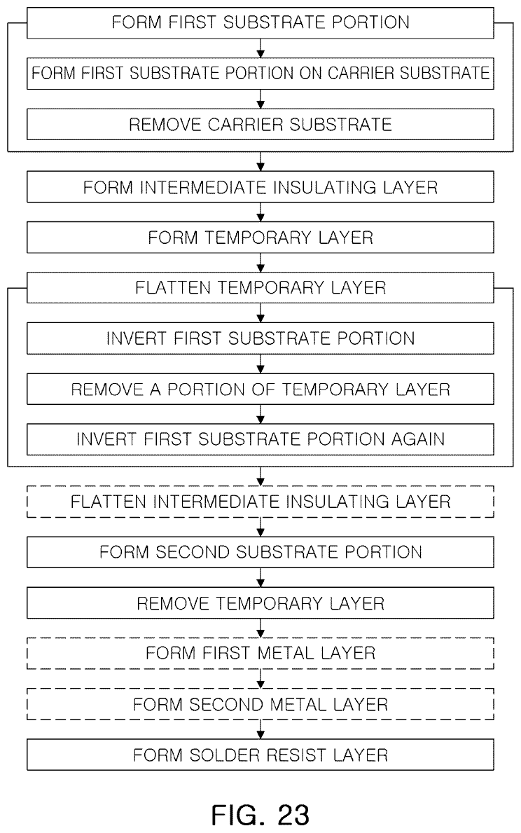

FIG. 23 is a flowchart illustrating a manufacturing method for a printed circuit board according to another example embodiment.

According to FIG. 23, a manufacturing method for a printed circuit board according to another example embodiment may include an operation of forming the first substrate portion 100, an operation of forming the intermediate insulating layer 250, an operation of forming the temporary layer 400, an operation of flattening the temporary layer 400, an operation of flattening the intermediate insulating layer 250, an operation of forming the second substrate portion 200, an operation of removing the temporary layer, an operation of forming the first metal layer 141, an operation of forming the second metal layer 142, and an operation of forming the solder resist layer SR.

The operation of forming the first substrate portion 100 may include an operation of forming the first substrate portion on a carrier substrate C and an operation of removing the carrier substrate C. Furthermore, the operation of flattening the temporary layer 400 may include an operation of inverting the first substrate portion 100, an operation of removing a portion of the temporary layer 400, and an operation of inverting the first substrate portion 100 again.

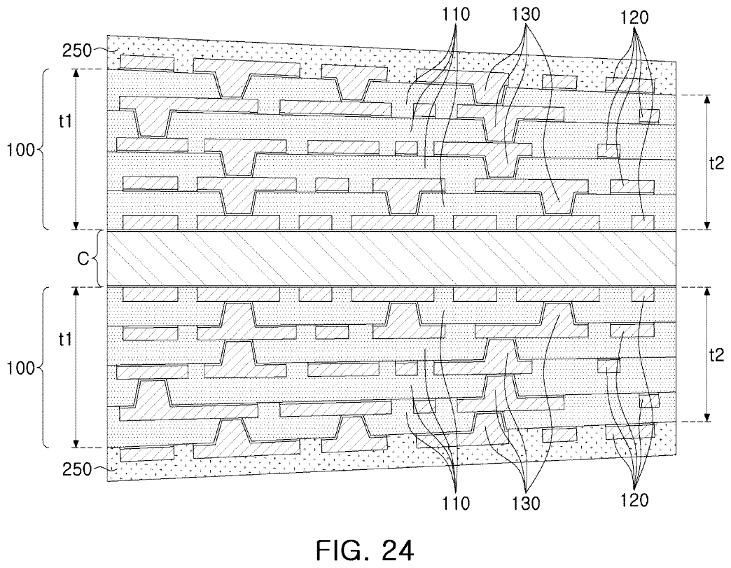

FIGS. 24 to 32 are cross-sectional views schematically illustrating a manufacturing method for a printed circuit board according to another example embodiment.

Referring to FIG. 24, a manufacturing method for a printed circuit board according to another example embodiment may include the operation forming the first substrate portion 100, and the operation forming the first substrate portion 100, which is the operation of forming the first substrate portion 100 on the carrier substrate C, may include an operation of forming a first insulating layer 110, a first wiring layer 120, and a first via layer 130 on the carrier substrate C.

That is, the first insulating layer 110 of the first substrate portion 100 may be comprised of a plurality of build-up insulating layers formed on the carrier substrate C without including a core insulating layer, and the first substrate portion 100 may have a structure of a so-called coreless substrate. The first substrate portion 100 may be formed by repeatedly stacking the first wiring layer 120 and the first insulating layer 110 on the carrier substrate C, and forming the first via layer 130 for connecting the first wiring layers 120 to each other.

In the manufacturing method for a printed circuit board according to another example embodiment, the first substrate portion 100 may have a coreless substrate structure, and thus have a structure in which the first wiring layer 120 disposed lowermost is buried by the first insulating layer 110 disposed lowermost. The fact that the first wiring layer 120 disposed lowermost is buried by the first insulating layer 110 disposed lowermost may denote that one surface of the first wiring layer 120 disposed lowermost may be exposed to one surface of the first insulating layer 110 disposed lowermost, and the remaining surface of the first wiring layer 120 disposed lowermost may be covered by the first insulating layer 110 disposed lowermost.

Although FIG. 24 illustrates that the first substrate portion is formed to be symmetrical above and below the carrier substrate C, the present disclosure is limited thereto, and the first substrate portion 100 may be formed only on one surface of the carrier substrate C.

The carrier substrate C may be composed of a core and seeds disposed above and below the core, but the present disclosure is not limited thereto, and the seed of the carrier substrate C may be composed of two stages. The core is meant to support the first insulating layer 110 and/or the first wiring layer 120 when forming the first insulating layer 110 and/or the first wiring layer 120, and may be formed of an insulating material or a metal material. The seed can be formed of copper, but is not particularly limited thereto. However, the carrier substrate C is an example of one case, and may be used without limitation by those skilled in the relevant technology field, and the carrier substrate C may be used as a temporary supporting means of the printed circuit board and may be used without particular limitation in the present disclosure as long as it can be later detected or removed.

The first substrate portion 100 having a coreless structure may also have a total thickness variation. That is, a thickness t1 of a first side surface of the first substrate portion 100 may be thicker than a thickness t2 of a second side facing the first side surface. However, since the first substrate portion 100 having the coreless structure stacks the first insulating layer 110 on the carrier substrate C, the thickness variation may not occur on the lower surface of the first substrate portion 100.

On the other hand, although FIG. 24 describes that the intermediate insulating layer 250 is formed on the first substrate portion 100 after forming the first substrate portion 100, the present disclosure is not limited thereto, and after removing the first substrate portion 100 from the carrier substrate C, the intermediate insulating layer 250 may be formed on the first substrate portion 100. That is, an order of forming the intermediate insulating layer 250 on the first substrate portion 100 may be before the carrier substrate C is removed or after the carrier substrate C is removed.

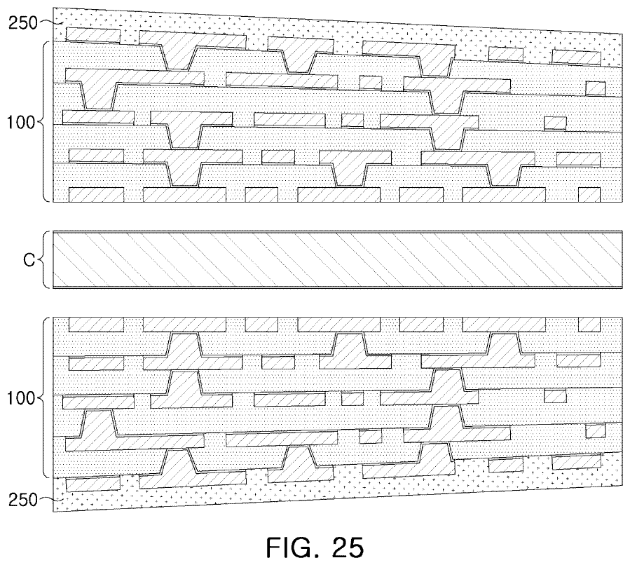

Referring to FIG. 25, in a manufacturing method for a printed circuit board according to another example embodiment, the operation of forming the first substrate portion 100 may include an operation of separating the first substrate portion 100 from the carrier substrate C. The carrier substrate C may be separated and removed from the first substrate portion 100, and the removal of the carrier substrate C may be performed by removing the core and seeds sequentially or collectively. The operation of separating the carrier substrate C may be performed by a process used for the detach of the carrier substrate C known in the relevant technology field.

Furthermore, FIG. 25 illustrates that the operation of removing the carrier substrate C is performed after forming the intermediate insulating layer 250 on the first substrate portion 100, but the intermediate insulating layer 250 may be formed on the first substrate portion 100 after removing the first substrate portion 100, as described above.

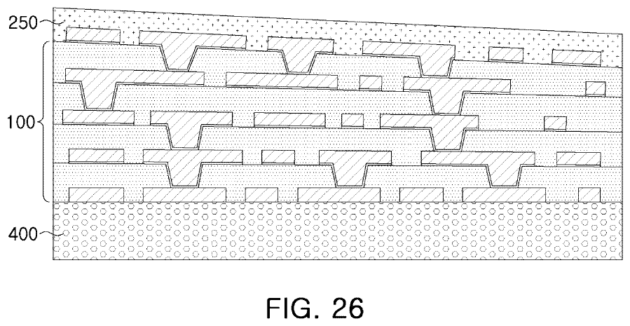

Referring to FIG. 26, a manufacturing method for a printed circuit board according to another example embodiment may include an operation of forming the temporary layer 400 on a surface opposite to a surface on which the intermediate insulating layer 250 of the first substrate portion 100 is formed, after the operation of forming the intermediate insulating layer 250 on the first substrate portion 100.

Because the printed circuit board according to another example embodiment may have a total thickness variation in an upper direction of the first substrate portion 100, the first insulating layer 110 disposed lowermost of the first substrate portion 100 may have a flat surface. Accordingly, the temporary layer 400 may be disposed in parallel with the lower surface of the first insulating layer 110 disposed lowermost of the first substrate portion 100, but the present disclosure is not necessarily limited thereto.

Among the descriptions of the temporary layer 400, the same content as the manufacturing method for a printed circuit board according to an example embodiment may also be applied to a manufacturing method for a printed circuit board according to another example embodiment, and thus, redundant descriptions thereof will be omitted.

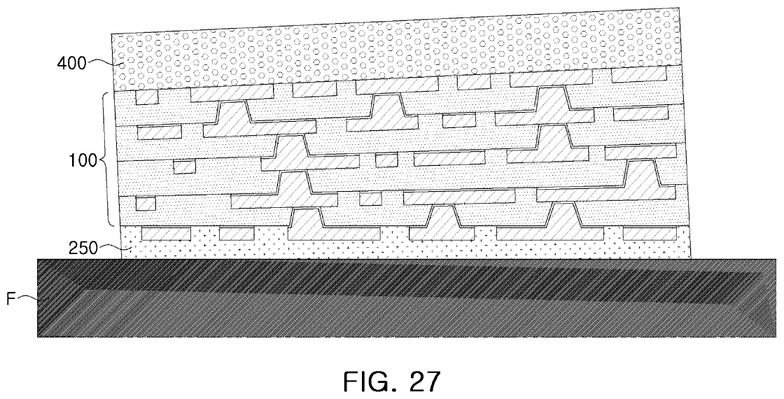

Referring to FIG. 27, the operation of flattening the temporary layer 400 in the manufacturing method for a printed circuit board according to another example embodiment may include an operation of inverting the first substrate portion 100 again so that the temporary layer 400 is disposed below the first substrate portion 100. In the description of the operation of inverting the first substrate portion 100, the same content as the manufacturing method for a printed circuit board according to an example embodiment may be applied in the same manner as a manufacturing method for a printed circuit board according to another example embodiment, and thus, redundant descriptions thereof will be omitted.

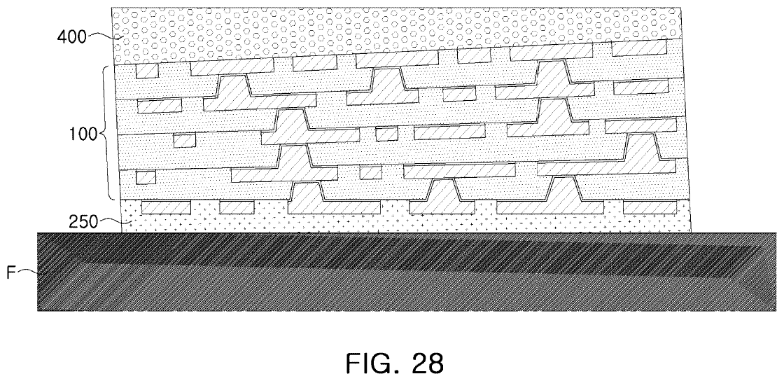

Referring to FIG. 28, the operation of flattening the temporary layer 400 in the manufacturing method for a printed circuit board according to another example embodiment may include an operation of flattening the temporary layer 400 by removing a portion of the temporary layer 400. In the description of the operation of flattening the temporary layer 400 by removing a portion of the temporary layer 400, the same content as the manufacturing method for a printed circuit board according to an example embodiment may be applied in the same manner as a manufacturing method for a printed circuit board according to another example embodiment, and thus, redundant descriptions thereof will be omitted.

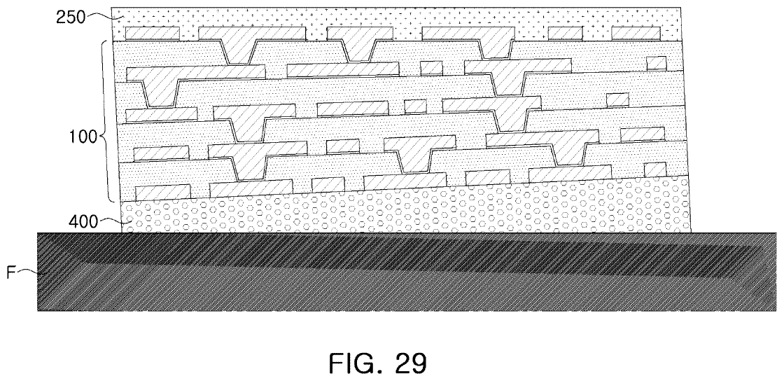

Referring to FIG. 29, the operation of flattening the temporary layer 400 in the manufacturing method for a printed circuit board according to another example embodiment may include an operation of inverting the first substrate portion 100 again so that the temporary layer 400 is disposed below the first substrate portion 100. In the description of the operation of inverting the first substrate portion 100 again, the same content as the manufacturing method for a printed circuit board according to an example embodiment may be applied in the same manner as a manufacturing method for a printed circuit board according to another example embodiment, and thus, redundant descriptions thereof will be omitted.

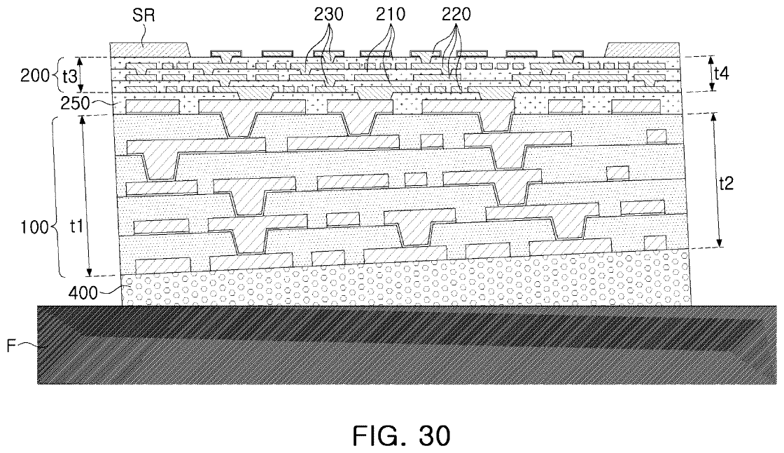

Referring to FIG. 30, a manufacturing method for a printed circuit board according to another example embodiment may include an operation of forming the second substrate portion 200 on the intermediate insulating layer 250. The operation of forming the second substrate portion 200 may include an operation of forming a plurality of second wiring layers 220, a plurality of second insulating layers 210 burying the plurality of second wiring layers 220, and a second via layer 230 penetrating through at least a portion of each of the plurality of second insulating layers 210. In the description of the operation of forming the second substrate portion 200, the same content as the manufacturing method for a printed circuit board according to an example embodiment may be applied in the same manner as a manufacturing method for a printed circuit board according to another example embodiment, and thus, redundant descriptions thereof will be omitted.

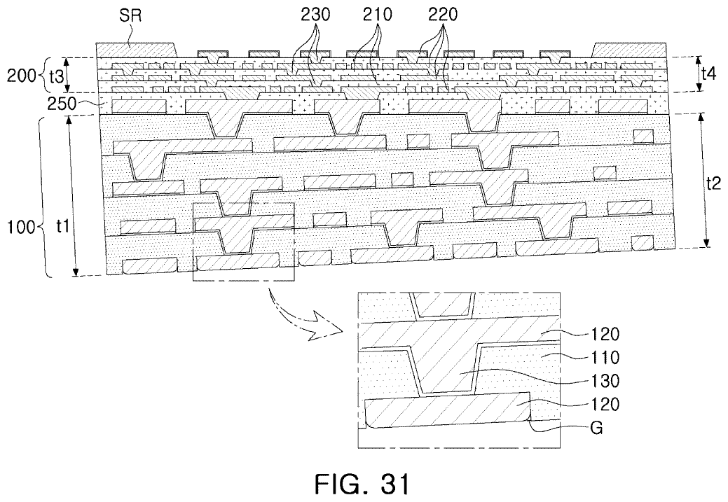

Referring to FIG. 31, a manufacturing method for a printed circuit board according to another example embodiment may include an operation of removing the temporary layer 400 after forming the second substrate portion 200.

The operation of removing the temporary layer 400 may be performed using at least one of a chemical-mechanical polishing (CMP) process and an etching process, but the present disclosure is not limited thereto.

In the case of using the chemical-mechanical polishing (CMP) process in the operation of removing the temporary layer 400, a portion of the first wiring layer 120 disposed lowermost may be removed. Because the chemical-mechanical polishing (CMP) process uses a chemical composition, at least a portion of an external circumferential surface of the first wiring layer 120 disposed lowermost may be removed to form a gap region G configured to separate the first wiring layer 120 disposed lowermost from the first insulating layer 110 disposed lowermost. That is, the gap region G may correspond to a trace from which a portion of the first wiring layer 120 disposed lowermost is removed. The gap region G may be formed along an external circumferential surface of a lower surface of the first wiring layer 120 disposed lowermost.

In the description of the operation of removing the temporary layer 400, the same content as the manufacturing method for a printed circuit board according to an example embodiment may be applied in the same manner as a manufacturing method for a printed circuit board according to another example embodiment, and thus redundant descriptions thereof will be omitted.

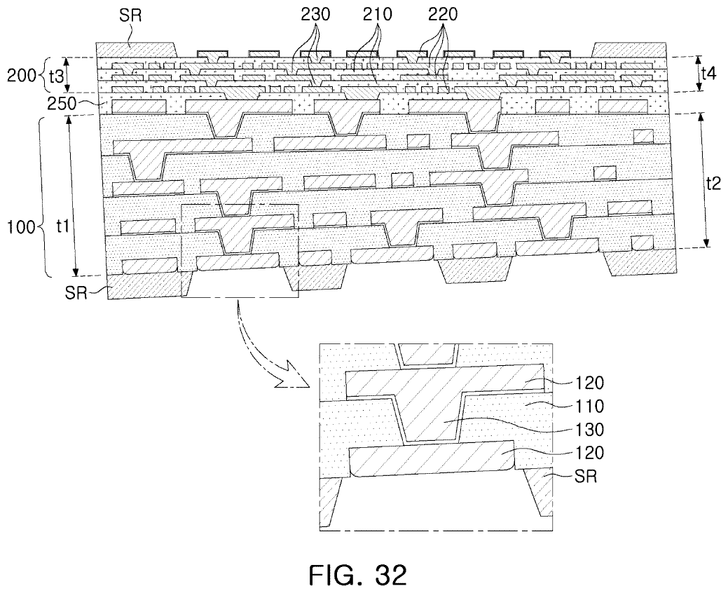

Referring to FIG. 32, a manufacturing method for a printed circuit board according to another example embodiment may further include an operation of forming a solder resist layer SR below the first substrate portion 100.

Since the printed circuit board according to another example embodiment has a coreless substrate structure, it many have a structure in which the first wiring layer disposed lowermost is embedded by the first insulating layer 110 disposed at the lowermost side. Because the first wiring layer 120 disposed at the lowermost side is buried by the first insulating layer 110 disposed at the lowermost side, damage to the first wiring layer disposed lowermost may be minimized in the operation of removing the temporary layer 400. Accordingly, the manufacturing method for a printed circuit board according to another example embodiment may not require the operation of forming the first metal layer 141 and the second metal layer 142, unlike the manufacturing method for a printed circuit board according to an example embodiment. Therefore, the printed circuit board may be completed by forming the solder resist layer SR below the first substrate portion 100.

On the other hand, in the description of the solder resist layer (SR), the same content as the manufacturing method for a printed circuit board according to an example embodiment may be applied in the same manner as a manufacturing method for a printed circuit board according to another example embodiment, and thus redundant descriptions thereof will be omitted.

Among other operations, the same operations as a manufacturing method for a printed circuit board according to an example embodiment, a manufacturing method for a printed circuit board according to the other example embodiments, and a manufacturing method for a printed circuit board according to another example embodiment may also be applied to a manufacturing method for a printed circuit board according to another example embodiment, and thus redundant descriptions thereof will be omitted.

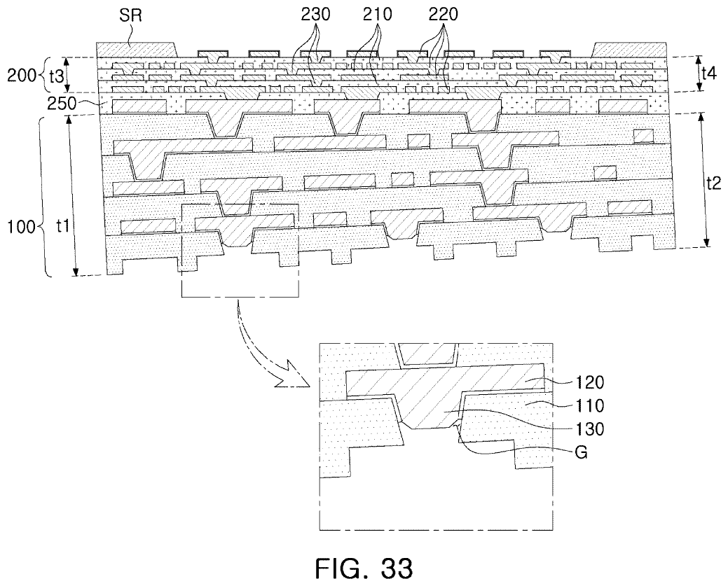

FIGS. 33 to 36 are cross-sectional views schematically illustrating a portion of a manufacturing method for a printed circuit board according to another example embodiment.

Referring to FIG. 33, the operation of removing the temporary layer 400 in the manufacturing method for a printed circuit board according to another example embodiment may be performed using an etching process.

In the case of using the etching process in the operation of removing the temporary layer 400, at least a portion of the first wiring layer 120 disposed lowermost may be removed and at least a portion of the lower surface of the first via layer 130 disposed lowermost may be exposed to the outside. A wet etching may be used as the etching, but the present disclosure is not limited thereto, and a dry etching may also be used.

In the case of using the etching process unlike using the chemical-mechanical polishing (CMP) process in the operation of removing the temporary layer 400, the first wiring layer 120 disposed lowermost may be removed, and the first via layer 130 disposed lowermost may be removed. That is, the first via layer 130 disposed lowermost may be exposed, and the lower surface of at least one first via of the first via layer 130 disposed lowermost may be disposed inside the first insulating layer 110 disposed lowermost. The lower surface of the first via layer 130 disposed lowermost and the lower surface of the first insulating layer 110 disposed lowermost may have mutual steps.

At least a portion of the external circumferential surface of the first via layer 130 disposed lowermost may be removed to form a gap region G for separating the first insulating layer 110 disposed lowermost from the first via layer 130 disposed lowermost. That is, the gap region G may correspond to a trace from which the first via layer 130 disposed lowermost is removed, and specifically, when the wet etching is performed, the gap region G may be formed along the external circumferential surface of the lower surface of the first via layer 130 disposed lowermost.

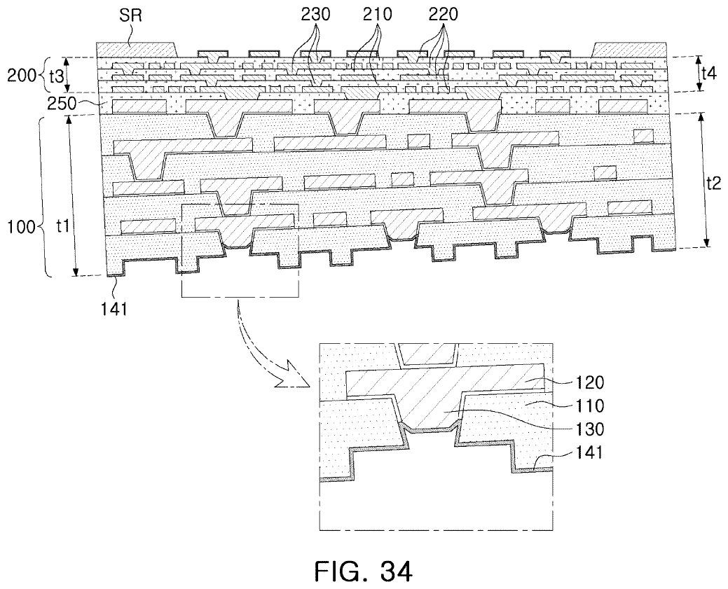

Referring to FIG. 34, a manufacturing method for a printed circuit board according to another example embodiment may further include an operation of forming the first metal layer 141 on at least a portion of the first insulating layer disposed lowermost, after removing the temporary layer 400. The first metal layer 141 may function as a seed layer in an operation of forming a second metal layer 142 described below.

Because the operation of forming the first metal layer 141 may be performed by electroless plating, the first metal layer 141 may be formed along the outside of the first insulating layer 110 disposed lowermost and the outside of the first via layer 130 disposed lowermost. Specifically, as a printed circuit board according to another example embodiment uses the etching process in the operation of removing the temporary layer 400, the first wiring layer disposed lowermost may be removed to expose a portion of a side surface of the first insulating layer 110 disposed lowermost. The first metal layer 141 may be formed to cover an exposed portion of the first insulating layer 110 disposed lowermost. The first metal layer 141 may be formed to extend along a boundary between the first insulating layer 110 disposed lowermost and the first via layer 130 disposed lowermost, and the first metal layer 141 may be formed to fill the gap region G.

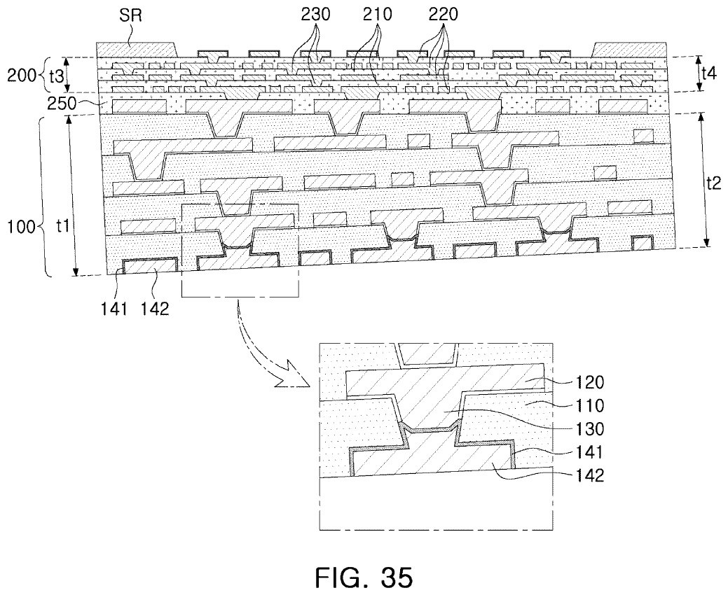

Referring to FIG. 35, a manufacturing method for a printed circuit board according to another example embodiment may include an operation of forming the second metal layer 142 on the first metal layer 141, after forming the first metal layer 141.

The second metal layer 142 may be formed using the first metal layer 141 as a seed layer. The second metal layer 142 may be formed to fit a region from which the first wiring layer 120 disposed lowermost is removed, and may be formed to fill the region from which the first wiring layer 120 disposed lowermost is removed and a region from which the first via layer 130 disposed lowermost is removed. Because the first metal layer 141 is formed inside the region from which the first wiring layer 120 is removed and then the second metal layer 142 is formed, the first metal layer 141 may also be disposed on a side surface of the second wiring layer 220. On the other hand, after the operation of forming the second metal layer 142, an operation of removing a portion of the first metal layer 141 may be further included, which is the same as the printed circuit board according to an example embodiment.

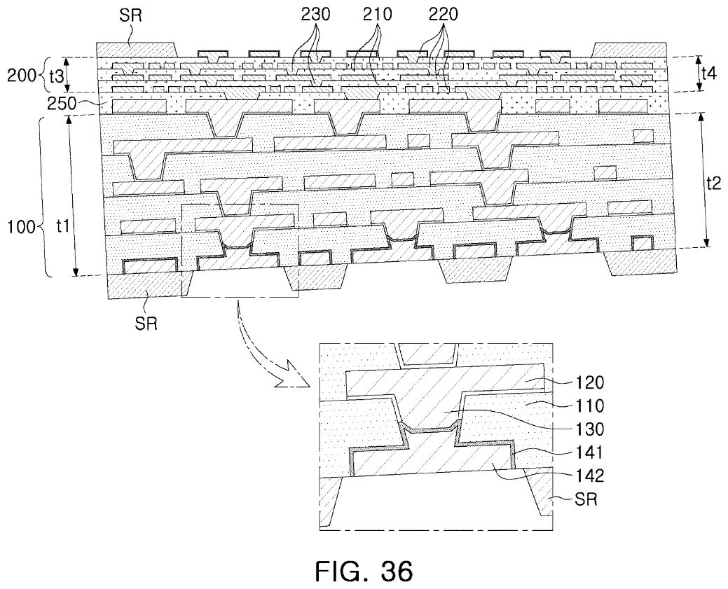

Referring to FIG. 36, a manufacturing method for a printed circuit board according to another example embodiment may further include an operation of forming the solder resist layer SR below the first substrate portion 100 after the operation of forming the second metal layer 142.

On the other hand, in the description of the solder resist layer SR, the same content as the manufacturing method for a printed circuit board according to an example embodiment may be applied in the same manner as a manufacturing method for a printed circuit board according to another example embodiment, and thus redundant descriptions thereof will be omitted.

Among other operations, the same operation as a manufacturing method for a printed circuit board according to an example embodiment, a manufacturing method for a printed circuit board according to the other example embodiments, and a manufacturing method for a printed circuit board according to another example embodiment may be applied to a manufacturing method for a printed circuit board according to another example embodiment, and thus redundant descriptions thereof will be omitted.

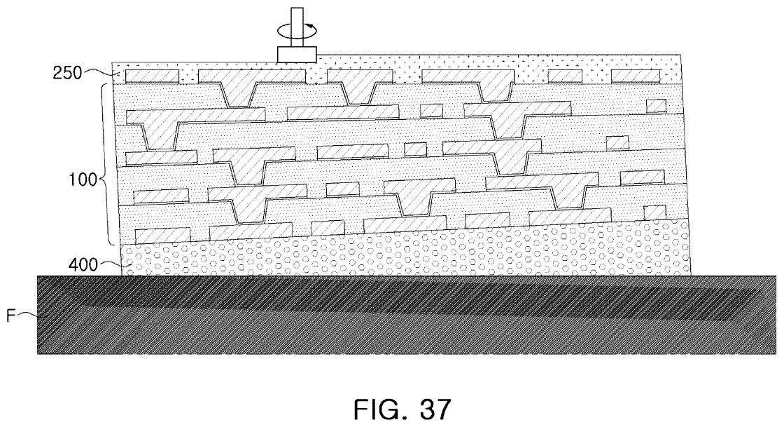

FIG. 37 is a cross-sectional view schematically illustrating a portion of a manufacturing method for a printed circuit board according to another example embodiment.

Referring to FIG. 37, a manufacturing method for a printed circuit board according to another example embodiment may further include an operation of flattening the intermediate insulating layer 250, before forming the second substrate portion 200. In the description of the operation of flattening the intermediate insulating layer 250, the same content as the manufacturing method for a printed circuit board according to another example embodiment may be applied in the same manner as a manufacturing method for a printed circuit board according to another example embodiment, and thus redundant descriptions thereof will be omitted.

Among other operations, the same operations as a manufacturing method for a printed circuit board according to an example embodiment, a manufacturing method for a printed circuit board according to the other example embodiments, and a manufacturing method for a printed circuit board according to another example embodiment may be applied to a manufacturing method for a printed circuit board according to another example embodiment, and thus redundant descriptions thereof will be omitted.

### Printed Circuit Board

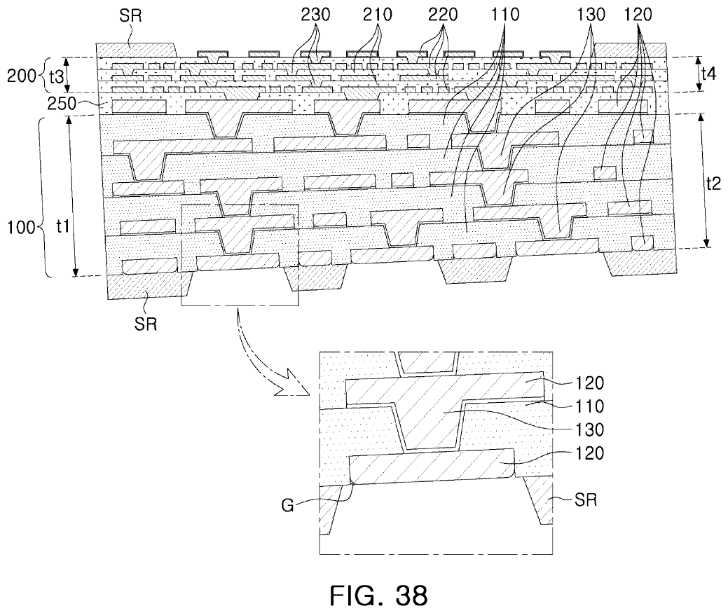

FIG. 38 is a cross-sectional view schematically illustrating a printed circuit board according to another example embodiment.

Referring to FIG. 38, a printed circuit board according to another example embodiment includes a first substrate portion 100 including a plurality of first insulating layers 110, a plurality of first wiring layers 120 respectively disposed on or in the plurality of first insulating layers 110, and a plurality of first via layers 130 penetrating through at least a portion of each of the plurality of first insulating layers 110, a second insulating layer 200 disposed on the first substrate portion 100, and an intermediate insulating layer 250 disposed between the first substrate portion 100 and the second substrate portion 200, and the first substrate portion 100 may include a gap region G for separating at least a portion of at least one first wiring of the first wiring layer 120 disposed lowermost, among the plurality of first wiring layers 120 from the first insulating layer 110 disposed lowermost among the plurality of first insulating layers 110, and at least a portion of a side surface of at least one first wiring of the first wiring layer 120 disposed lowermost may be buried by the first insulating layer 110 disposed lowermost among the plurality of first insulating layers 110.

A printed circuit board according to another example embodiment may include a gap region G for separating a portion of at least one first wiring of the first wiring layer 120 disposed lowermost from the first insulating layer 110 disposed lowermost. The gap region G may correspond to a trace from which a portion of the first wiring is removed in the manufacturing method for a printed circuit board according to an example embodiment. Since the manufacturing method for a printed circuit board according to an example embodiment may use a chemical-mechanical polishing (CMP) process in the operation of removing the temporary layer (400), as described above, a portion of the first wiring of the first wiring layer 120 disposed lowermost may be removed, thus generating the gap region G.

A total thickness variation may occur in the first substrate portion 100 of the printed circuit board according to another example embodiment, as described above in the manufacturing method for a printed circuit board according to an example embodiment, and the manufacturing method for a printed circuit board according to another example embodiment. That is, the first substrate portion 100 may have a total thickness variation, a thickness t1 of a first side surface of the first substrate portion 100 may be thicker than a thickness t2 of a second side surface facing the first side surface, and the first substrate portion 100 may have an inclined structure in which the thickness t1 of the first side surface is the thickest and the thickness t2 of the second side surface is the thinnest. On the other hand, a thickness t3 of a first side surface of the second substrate portion 200 may be substantially the same as a thickness t4 of a second side surface facing the first side surface. Despite the total thickness variation of the first substrate portion 100, the second substrate portion 200 may be disposed on a flattened intermediate insulating layer 250. Because the second substrate portion 200 may include a wiring finer than a wiring of the first substrate portion 100, the second substrate portion 200 may have little total thickness variation.

On the other hand, other descriptions of the configuration of a printed circuit board according to another example embodiment may be applied in the same manner as described above in a manufacturing method for a printed circuit board according to an example embodiment, a manufacturing method for a printed circuit board according to the other example embodiments and a manufacturing method for a printed circuit board according to another example embodiment, and thus redundant descriptions of the same configuration will be omitted.

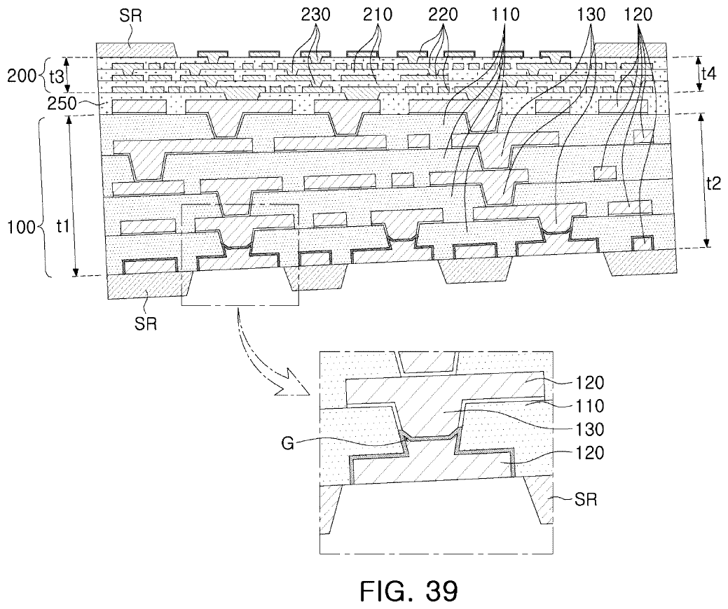

FIG. 39 is a cross-sectional view schematically illustrating a printed circuit board according to another example embodiment.

Referring to FIG. 39, a first wiring layer 120 disposed lowermost of another printed circuit board may include a first metal layer 141 and a second metal layer 142, and a boundary surface between at least one first via of a first via layer 130 disposed lowermost and the first metal layer 141 may be disposed inside a first insulating layer 110 disposed lowermost. Furthermore, the printed circuit board may include a first substrate portion 100 including a plurality of first insulating layers 110, a plurality of first wiring layers 120 respectively disposed on or in the plurality of first insulating layers 110, and a plurality of first via layers 130 penetrating through at least a portion of each of the plurality of first insulating layers 110, a second insulating layer 200 disposed on the first substrate portion 100, and an intermediate insulating layer 250 disposed between the first substrate portion 100 and the second substrate portion 200, and the first substrate portion 100 may include a gap region G for separating at least a portion of at least one first via of the first via layer 130 disposed lowermost, among the plurality of first via layers 130, from the first insulating layer 110 disposed lowermost among the plurality of first insulating layers 110.

This corresponds to a result of using the etching process in the operation of removing the temporary layer 400 in the manufacturing method for a printed circuit board according to another example embodiment. In other words, unlike the printed circuit board according to another example embodiment, the first wiring layer 120 disposed lowermost may be removed and a portion of the first via layer 130 disposed lowermost is removed together, so that a lower surface of at least one first via of the first via layer 130 disposed lowermost may be disposed in the first insulating layer 110 disposed lowermost. If the etching process is used in the operation of removing the temporary layer 400, more portions of the first wiring layer 120 disposed lowermost and the first via layer 130 disposed lowermost may be removed than in the case of using the chemical-mechanical polishing (CMP) process. Because portions of the first wiring layer 120 disposed lowermost and the first via layer 130 disposed lowermost have been removed, the first wiring layer disposed lowermost of the printed circuit board according to another example embodiment may include a first metal layer 141 and a second metal layer 142. Furthermore, the first metal layer 141 may be disposed along the boundary between the first insulating layer 110 disposed lowermost and the second metal layer 142, and the first wiring layer 120 disposed lowermost may be disposed to fill a region from which a portion of the first via layer 130 disposed lowermost is removed.

On the other hand, other descriptions of the configuration of a printed circuit board according to another example embodiment may be applied in the same manner as described above in a manufacturing method for a printed circuit board according to an example embodiment, a manufacturing method for a printed circuit board according to the other example embodiments, and a manufacturing method for a printed circuit board according to another example embodiment, and thus redundant descriptions of the same configuration is omitted.

In the present disclosure, a meaning on the cross-section may denote a cross-sectional shape when an object is vertically cut, or a cross-sectional shape when the object is viewed from a side-view. Furthermore, a meaning on the plane may be a shape when the object is horizontally cut, or a planar shape when the object is viewed in a top-view or a bottom-view.

In the present disclosure, for convenience, an upper side, an upper portion, an upper surface, and the like, are used to refer to a direction facing a surface on which an electronic component may be mounted based on a cross-section of a drawing, and a lower side, a lower portion, a lower surface, and the like, are used in an opposite direction thereof. However, this defines the direction for convenience of explanation, and the scope of rights of the claims is not particularly limited by the description of such a direction.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression “example embodiment used in the present disclosure” does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A manufacturing method for a printed circuit board, the method comprising:
forming a first substrate portion;
forming an intermediate insulating layer on the first substrate portion;
forming a temporary layer on a surface opposite to a surface on which the intermediate insulating layer of the first substrate portion is formed;
flattening the temporary layer;
forming a second substrate portion on the intermediate insulating layer; and
removing the temporary layer.

2. The manufacturing method for a printed circuit board according to claim 1, wherein the flattening the temporary layer comprises:
inverting the first substrate portion so that the temporary layer is disposed above the first substrate portion;
flattening the temporary layer by removing a portion of the temporary layer, and
inverting the first substrate portion again so that the temporary layer is disposed below the first substrate portion.

3. The manufacturing method for a printed circuit board according to claim 1, wherein a thickness, along a first side surface of the first substrate portion, of the first substrate portion, is thicker than a thickness, along a second side surface facing the first side surface of the first substrate portion, of the first substrate portion.

4. The manufacturing method for a printed circuit board according to claim 3,
wherein the first substrate portion is inclined so that a thickness along the first side surface thereof is the thickest and a thickness along the second side surface thereof is the thinnest.

5. The manufacturing method for a printed circuit board according to claim 1,
wherein the temporary layer includes a metal.

6. The manufacturing method for a printed circuit board according to claim 5,
wherein the forming the temporary layer is performed by plating.

7. The manufacturing method for a printed circuit board according to claim 1,
wherein the removing the temporary layer is performed using at least one of chemical-mechanical polishing (CMP) and etching.

8. The manufacturing method for a printed circuit board according to claim 1,
wherein the forming the first substrate portion comprises:
forming a plurality of first wiring layers, a plurality of first insulating layers respectively burying the plurality of first wiring layers, and a first via layer penetrating through at least a portion of one or more of the plurality of first insulating layers.

9. The manufacturing method for a printed circuit board according to claim 8,
wherein in the removing the temporary layer, at least a portion of a first wiring layer disposed lowermost, among the plurality of first wiring layers, is removed, and at least a portion of a first via layer disposed lowermost, among the plurality of first via layers, is exposed to the outside.

10. The manufacturing method for a printed circuit board according to claim 9,
wherein in the removing the temporary layer, at least a portion of an external circumferential surface of the first via layer disposed lowermost is further removed to form a gap region for separating at least a portion of the first via layer disposed lowermost from a first insulating layer disposed lowermost among the plurality of first insulating layers.

11. The manufacturing method for a printed circuit board according to claim 10, further comprising: after the removing the temporary layer,
forming a first metal layer on at least a portion of the first insulating layer disposed lowermost; and
forming a second metal layer on the first metal layer.

12. The manufacturing method for a printed circuit board according to claim 11,
wherein the first metal layer extends from the first insulating layer disposed lowermost to the first via layer disposed lowermost and fills the gap region.

13. The manufacturing method for a printed circuit board according to claim 11,
wherein the forming the first metal layer is performed by electroless plating, and
the forming the second metal layer is performed by electroplating.

14. The manufacturing method for a printed circuit board according to claim 11, further comprising:
after the forming the second metal layer, forming a solder resist layer on the first insulating layer disposed lowermost.

15. The manufacturing method for a printed circuit board according to claim 8,
wherein the forming the second substrate portion comprises:
forming a plurality of second wiring layers, a plurality of second insulating layers respectively burying the plurality of second wiring layers, and a second via layer penetrating through at least a portion of one or more of the plurality of second insulating layers, and
the second substrate portion includes a wiring finer than a wiring of the first substrate portion.

16. The manufacturing method for a printed circuit board according to claim 1, further comprising:
before the forming the second substrate portion on the intermediate insulating layer,
flattening the intermediate insulating layer.

17. The manufacturing method for a printed circuit board according to claim 1, further comprising: after the removing the temporary layer,
forming a third substrate portion on a surface opposite to a surface on which the second substrate portion of the first substrate portion is formed,
wherein the forming a third substrate portion comprises:
forming a third insulating layer, a third wiring layer formed on the third insulating layer, and a third via layer penetrating through at least a portion of the third insulating layer to be connected to the third wiring layer.

18. A printed circuit board comprising:
a first substrate portion including a plurality of first insulating layers, a plurality of first wiring layers respectively disposed on or in the plurality of first insulating layers, and a plurality of first via layers penetrating through at least a portion of one or more of the plurality of first insulating layers;
a second substrate portion disposed on the first substrate portion; and
an intermediate insulating layer disposed between the first and second substrate portions,
wherein at least one first wiring of a first wiring layer disposed lowermost, among the plurality of first wiring layers, is disposed on the first via, and
the first substrate portion includes a gap region for separating at least a portion of at least one first via of a first via layer disposed lowermost, among the plurality of first via layers, from a first insulating layer disposed lowermost, among the plurality of first insulating layers.

19. The printed circuit board according to claim 18,
wherein the first wiring includes a first metal layer disposed on the first via and a second metal layer disposed on the first metal layer.

20. The printed circuit board according to claim 19,
wherein the first metal layer extends to a first insulating layer disposed lowermost, among the plurality of first insulating layers and is disposed in the gap region.

21. The printed circuit board according to claim 20,
wherein a boundary surface between the first via and the first metal layer is disposed inside the first insulating layer disposed lowermost, and
the boundary surface between the first via and the first metal layer and a lower surface of the first insulating layer disposed lowermost have a step portion.

22. The printed circuit board according to claim 18,
wherein a thickness, along a first side surface of the first substrate portion, of the first substrate portion is thicker than a thickness, along a second side surface facing the first side surface of the first substrate portion, of the first substrate portion.

23. The printed circuit board according to claim 22,
wherein the first substrate portion is inclined so that a thickness along the first side surface thereof is the thickest and a thickness along the second side surface thereof is the thinnest.

24. The printed circuit board according to claim 23,
wherein a thickness, along a first side surface of the second substrate portion, of the second substrate portion is substantially identical to a thickness, along a second side surface facing the first side surface of the second substrate portion, of the second substrate portion.

25. The printed circuit board according to claim 18,
wherein the second substrate portion includes a plurality of second insulating layers, a plurality of second wiring layers respectively disposed on or in the plurality of second insulating layers, and a plurality of second via layers penetrating through at least a portion of one or more of the plurality of second insulating layers, and
the second substrate portion includes a wiring finer than a wiring of the first substrate portion.

26. The printed circuit board according to claim 25,
wherein a roughness of an upper surface of an insulating layer disposed lowermost, among the plurality of second insulating layers, is greater than a roughness of an upper surface of a remaining insulating layer except for an insulating layer disposed lowermost, among the plurality of second insulating layers.

27. The printed circuit board according to claim 18, further comprising:
a third substrate portion disposed on a surface opposite to a surface on which the second substrate portion of the first substrate portion is disposed,
wherein the third substrate portion includes a third insulating layer, a third wiring layer formed on the third insulating layer, and a third via layer penetrating through at least a portion of the third insulating layer.

28. A printed circuit board comprising:
a first substrate portion including a plurality of first insulating layers, a plurality of first wiring layers respectively disposed on or in the plurality of first insulating layers, and a plurality of first via layers penetrating through at least a portion of one or more of the plurality of first insulating layers; and
a second substrate portion disposed on the first substrate portion,
wherein the first substrate portion includes a gap region for separating at least portion of a first wiring of a first wiring layer disposed lowermost, among the plurality of first wiring layers, from a first insulating layer disposed lowermost, among the plurality of first insulating layers, and
at least a portion of a side surface of the first wiring is embedded by the first insulating layer disposed lowermost, among the plurality of first insulating layers.

29. A manufacturing method for a printed circuit board, the method comprising:
forming a first substrate portion;
forming an intermediate insulating layer on the first substrate portion;
forming a temporary layer on a surface opposite to a surface on which the intermediate insulating layer of the first substrate portion is formed;
leveling an exterior surface of the temporary layer by thinning the temporary layer, such that the exterior surface of the temporary layer after leveling is substantially parallel to a surface of the intermediate insulating layer opposite to the first substrate portion;
forming a second substrate portion on the intermediate insulating layer; and
removing the temporary layer.

30. The manufacturing method for a printed circuit board according to claim 29, wherein a thickness, along a first side surface of the first substrate portion, of the first substrate portion, is thicker than a thickness, along a second side surface facing the first side surface of the first substrate portion, of the first substrate portion.

31. The manufacturing method for a printed circuit board according to claim 30, wherein after leveling, a thickness, along a first side surface of the temporary layer which is on a same side as the first side surface of the first substrate portion, of the temporary layer, is less than a thickness, along a second side surface of the temporary layer which is on a same side as the second side surface of the first substrate portion, of the temporary layer.

32. The manufacturing method for a printed circuit board according to claim 29,
wherein the removing the temporary layer is performed using at least one of chemical-mechanical polishing (CMP) and etching.

33. The manufacturing method for a printed circuit board according to claim 29,
wherein the forming the first substrate portion comprises:
forming a plurality of first wiring layers, a plurality of first insulating layers respectively burying the plurality of first wiring layers, and a first via layer penetrating through at least a portion of one or more of the plurality of first insulating layers.

34. The manufacturing method for a printed circuit board according to claim 29,
wherein the forming the second substrate portion comprises:
forming a plurality of second wiring layers, a plurality of second insulating layers respectively burying the plurality of second wiring layers, and a second via layer penetrating through at least a portion of one or more of the plurality of second insulating layers, and
the second substrate portion includes a wiring finer than a wiring of the first substrate portion.

35. The manufacturing method for a printed circuit board according to claim 29, further comprising:
before the forming the second substrate portion on the intermediate insulating layer,
flattening the intermediate insulating layer.

36. A printed circuit board comprising:
a first substrate portion including a plurality of first insulating layers, a plurality of first wiring layers respectively disposed on or in the plurality of first insulating layers, and a plurality of first via layers penetrating through at least a portion of one or more of the plurality of first insulating layers;
a second substrate portion disposed on the first substrate portion, and including a plurality of second insulating layers, a plurality of second wiring layers respectively disposed on or in the plurality of second insulating layers, and a plurality of second via layers penetrating through at least a portion of one or more of the plurality of second insulating layers; and
an intermediate insulating layer disposed between the first and second substrate portions,
wherein a thickness, along a first side surface of the second substrate portion, of the second substrate portion is substantially identical to a thickness, along a second side surface facing the first side surface of the second substrate portion, of the second substrate portion, and
a thickness, along a first side surface of the first substrate portion, of the first substrate portion is thicker than a thickness, along a second side surface facing the first side surface of the first substrate portion, of the first substrate portion.

37. The printed circuit board according to claim 36,
wherein the first substrate portion is inclined so that a thickness along the first side surface thereof is the thickest and a thickness along the second side surface thereof is the thinnest.

38. The printed circuit board according to claim 36,
the second substrate portion includes a wiring finer than a wiring of the first substrate portion.

39. The printed circuit board according to claim 36,
wherein a roughness of an upper surface of an insulating layer disposed lowermost, among the plurality of second insulating layers, is greater than a roughness of an upper surface of a remaining insulating layer except for an insulating layer disposed lowermost, among the plurality of second insulating layers.

40. The printed circuit board according to claim 36, further comprising:
a solder resist layer disposed on the second substrate portion and including an opening exposing patterns of an uppermost one of the plurality of second wiring layers.
